(19) United States
(12) Patent Application Publication
(10) Pub. No.: US 2026/0033323 A1
(43) Pub. Date: Jan. 29, 2026

(54) HIGH VOLTAGE ISOLATION WITH CONTROLLED DISCHARGE PATH

(71) Applicant: TEXAS INSTRUMENTS INCORPORATED, Dallas, TX (US)

(72) Inventors: Jeffrey Alan West, Dallas, TX (US); Byron Williams, Plano, TX (US); Elizabeth Costner Stewart, Dallas, TX (US); Weijie Xu, Garland, TX (US); Pijush Kanti Ghosh, Sachse, TX (US)

(21) Appl. No.: 18/786,203

(22) Filed: Jul. 26, 2024

(51) Int. Cl. H01L 23/522; H01L 23/00; H01L 25/065; H01L 27/06

(52) U.S. Cl. CPC H01L 23/5223; H01L 25/0655; H10D 1/692; H10D 84/811; H01L 24/32; H01L 24/48; H01L 24/73; H01L 2224/32245; H01L 2224/48138; H01L 2224/48464; H01L 2224/73265; H01L 2924/19041

(57) ABSTRACT

A semiconductor device including a capacitive HV isolation component and a method of fabrication thereof is disclosed. In one example, the semiconductor device comprises a semiconductor substrate, a bottom capacitor plate over the semiconductor substrate, a top capacitor plate over the bottom capacitor plate, and one or more conductive posts extending between the bottom plate and the top plate.

### FIELD OF THE DISCLOSURE

Disclosed implementations relate generally to the field of integrated circuits (ICs) and IC fabrication. More particularly, but not exclusively, the disclosed implementations relate to an IC including a high voltage isolation component.

### BACKGROUND

Galvanic isolation is a principle of isolating functional sections of electrical systems or integrated circuits to prevent current flow while energy or information can still be exchanged between the sections by other means, such as capacitance, induction or electromagnetic waves, or by optical, acoustic or mechanical means. Galvanic isolation is typically used where two or more electric circuits communicate but their grounds or reference nodes may be at different potentials. It is an effective method of breaking ground loops by preventing unwanted current from flowing between two units sharing a reference conductor. Galvanic isolation is also used for safety, preventing accidental current flows from reaching ground through a person's body.

Isolators are devices designed to minimize direct current (DC) and unwanted alternating or transient currents between two systems or circuits, while allowing data and power transmission between the two. In most applications, isolators also act as a barrier against high voltage in addition to allowing the system to function properly. Where capacitive elements are used as isolators, dielectric breakdown is a key concern, especially in high voltage (HV) applications.

As the advances in the design of integrated circuits and semiconductor fabrication continue to take place, improvements in microelectronic devices, including galvanic isolators, are also being concomitantly pursued.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC device (also referred to as an electronic device, semiconductor device, etc.) including a capacitive HV isolation component where discharge paths from a top plate of the HV isolation component may be controllably directed through better characterized dielectric layers, thus facilitating more reliable predictions with respect to the IC's time-dependent quality and performance indicators.

In one example, an IC device is disclosed, which comprises, among others, a semiconductor substrate, a bottom capacitor plate over the semiconductor substrate, a top capacitor plate over the bottom capacitor plate, and one or more conductive posts extending between the bottom plate and the top plate. In some arrangements, the conductive post(s) may be configured to direct a discharge path between the top plate and the bottom plate through a dielectric stack disposed between the bottom plate and the top plate.

In one example, an IC package is disclosed, which comprises, among others, a first IC die including: a capacitor including bottom capacitor plate over a first semiconductor substrate, a top capacitor plate over the bottom capacitor plate, and a conductive post between the bottom capacitor plate and the top capacitor plate; a second IC die including a circuit over or extending into a second semiconductor substrate; and a wire bond connecting the top capacitor plate to the circuit.

In one example, a method of fabricating an IC is disclosed, which comprises among others, forming a metal bottom plate of a capacitor over a semiconductor substrate; forming a conductive post over the bottom plate; and forming a metal top plate of the capacitor over the conductive post, wherein the conductive post extends between the bottom plate and the top plate.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A-1 to 1A-3 illustrate cross-sectional views of a semiconductor device including a capacitive HV isolation component and a conductive post arrangement according to three examples, respectively;

FIG. 1B illustrates a top plan view of a semiconductor device according to some examples;

FIGS. 2A-2Q illustrate sectional views of a semiconductor device at progressive stages of manufacturing according to some examples; and

FIGS. 3A and 3B are flowcharts relating to IC fabrication methods according to some examples;

FIG. 4 is a partial cross-sectional view of an IC package according to some examples; and

FIGS. 5A-5C depict plan views of a metal plate of an isolation component with a plurality of conductive posts operable as discharge path direction conductors according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of a high voltage isolation component and a method of manufacturing the same will be set forth below in the context of capacitive isolation devices formed in the interconnect levels of an IC device during back-end-of-line (BEOL) fabrication.

Circuit isolation, also known as galvanic isolation, may prevent direct current (DC) and unwanted alternating current (AC) signals from passing from one area of a system or a circuit to another area or circuit that needs to be protected, as previously noted. Among its uses, isolation may maintain signal integrity of the system or circuit by preventing high-frequency noise from propagating, protecting sensitive circuitry from high-voltage surges and spikes, and providing safety for human operators.

The high voltages present in factory automation, motor drives, grid infrastructure and electric vehicles (EVs), etc., can be several hundreds or even thousands of volts. Galvanic isolation helps resolve the challenge of designing a safe human interface in the presence of such high voltages.

In some example implementations, galvanic isolators may be created by forming a parallel-plate capacitor using electrodes in different metallization layers of the integrated circuit, such as different metallization layers in the BEOL interconnect levels. The dielectric layers of the BEOL levels separate the electrodes to form the capacitor, where a stack of dielectric layers may form the capacitor's distance through isolation (DTI). For HV applications, the thickness of BEOL dielectric layers and/or the number of BEOL dielectric layers may be increased to provide a higher DTI, thus improving the breakdown performance of the capacitor (e.g., increasing the breakdown voltage of the capacitor). In some examples, a composite dielectric layer comprising silicon nitride (SiN) and silicon oxynitride (SiON) may be provided under the top electrode for improving HV isolation performance.

Despite the advances in controlling the quality and/or composition of BEOL dielectric layers, thus the DTI of a galvanic isolator, certain types of failure modes associated with galvanic isolators remain, leading to ongoing reliability issues. For example, the maximum or intrinsic capability of galvanic isolation capacitors can be limited by early lifetime failures, which may be caused due to breakdown of materials disposed over and/or laterally adjacent to a top plate of the capacitor in the presence of high electric fields, e.g., on the order of several hundreds of volts/μm or kilovolts/μm, without limitation. In example implementations, materials over and/or laterally adjacent to the top plate generally comprise passivation, protective overcoat and/or mold compounds, etc., that have poorer dielectric breakdown strengths than the materials (e.g., SiO₂, etc.) comprising the DTI. Polyimide and mold compounds, for example, are susceptible to degraded isolation due to moisture uptake and to degraded lifetime when stressed at higher frequencies. Additionally, interface(s) between the protective overcoat and top metal plate/mold compounds are also susceptible to less reliable characterization.

Examples of the present disclosure recognize the foregoing challenges and provide a technical solution for controlling failure paths, also referred to herein as discharge paths, of an isolation capacitor that may be caused in the presence of high electric fields. To prevent lateral and/or upward failure paths across or over an IC device, and instead direct the failure paths to travel downward, e.g., through the capacitor DTI, examples herein may include one or more conductive posts positioned relative to the top and/or bottom plates of the isolation capacitor that may operate as a “hot spot” to preferentially draw and terminate the failure paths. Because the downward failure paths are directed through DTI materials of higher dielectric strength, more reliable quality estimates and working voltage projections of the IC device may be obtained. While such examples and variations may be expected to increase overall reliability and/or electrical performance of IC devices, no particular result is a requirement unless explicitly recited in a particular claim.

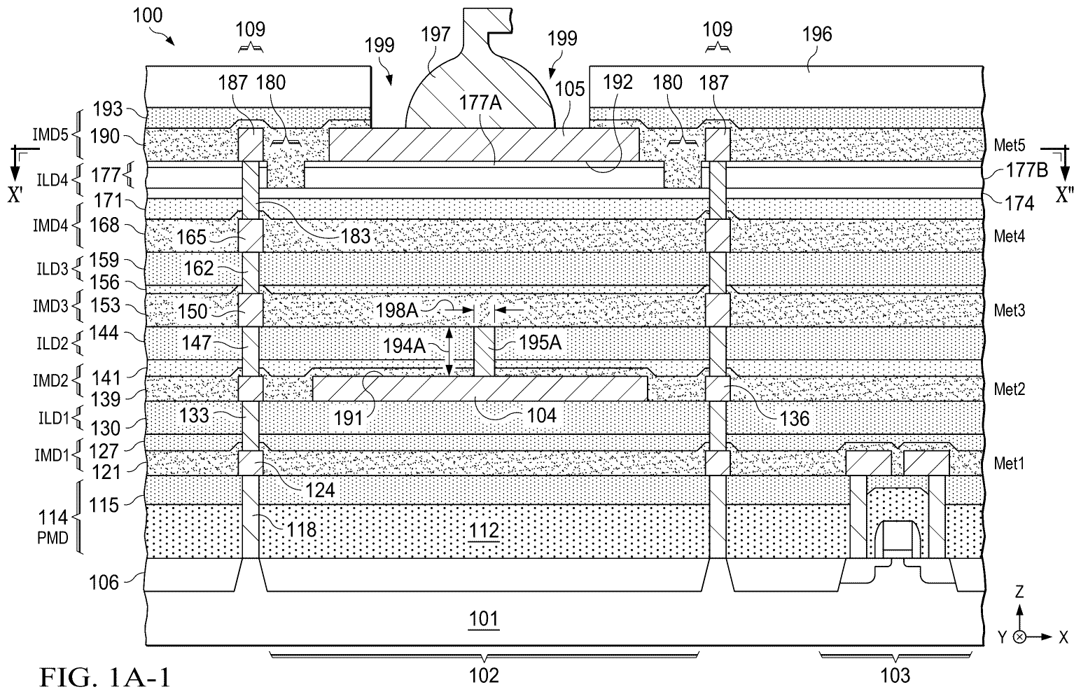

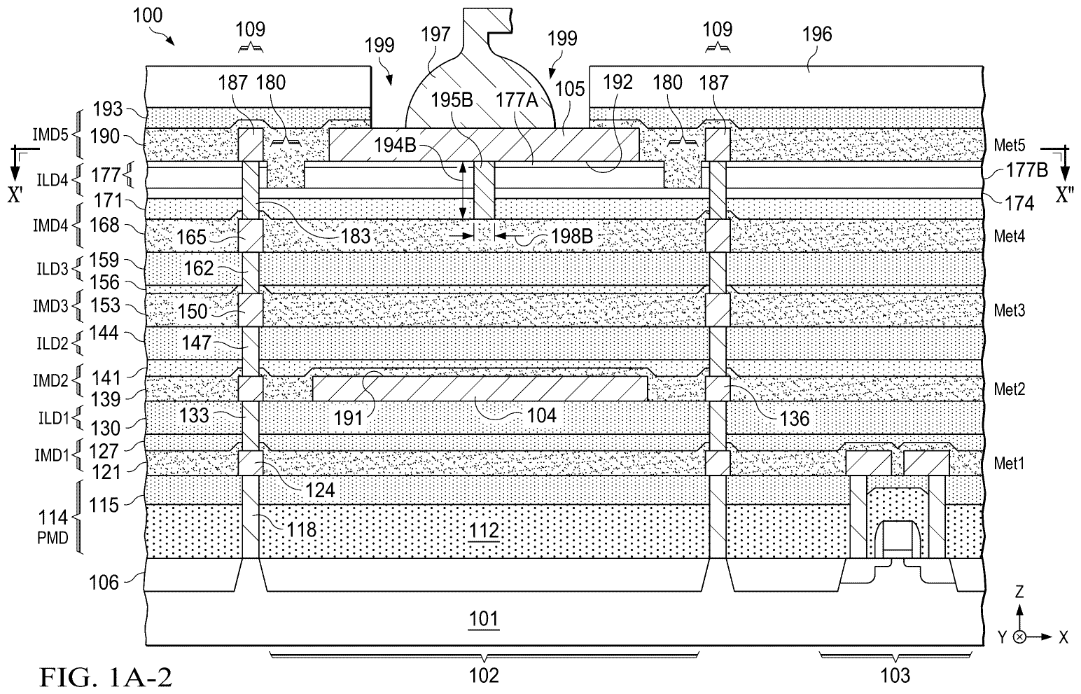

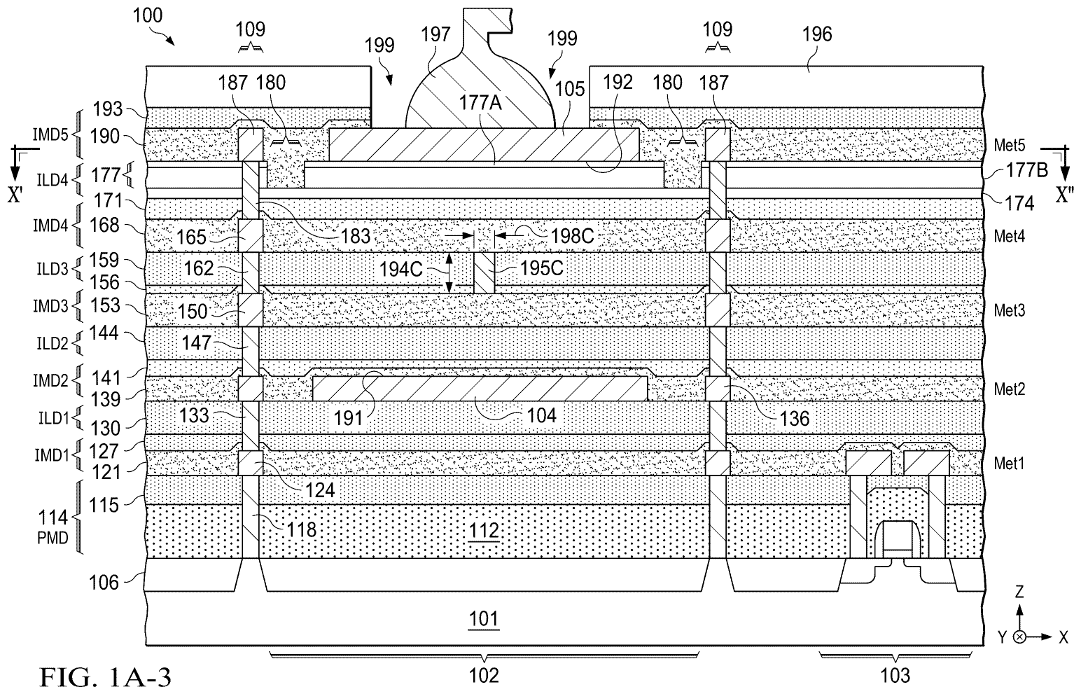

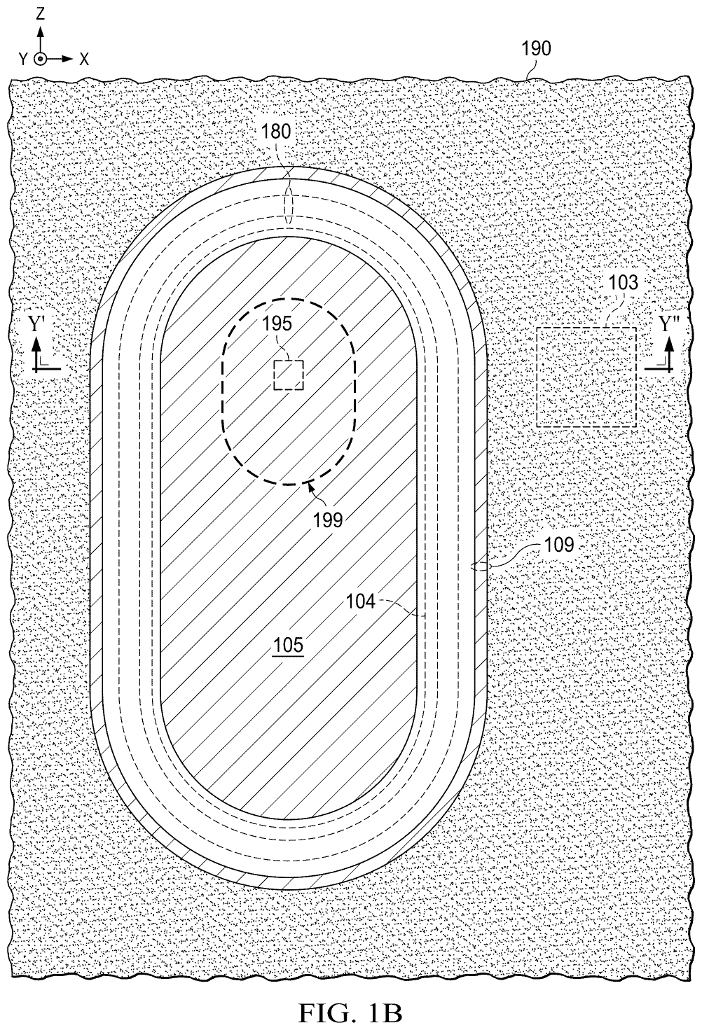

Turning to FIGS. 1A-1 to 1A-3, three representative examples of a semiconductor device 100, e.g., an IC device, are shown in respective sectional views, where a capacitive HV isolation component as well as a conductive post operable as a discharge path component may be provided according to some implementations herein. As will be set forth in detail further below, one or more conductive posts may be fabricated during BEOL processing of the semiconductor device 100, where the conductive posts may be formed as metallic structures that do not electrically connect between metal interconnect layers of a multilevel metallization scheme associated with the semiconductor device 100. Further, the conductive posts may be positioned on various levels and/or at locations relative to the conductive structures, e.g., electrodes, of the HV isolation component depending on implementation.

Referring to FIG. 1A-1 in particular, the semiconductor device 100 includes a semiconductor substrate 101 where a capacitor 102 operable as a galvanic HV isolation device and an optional transistor 103 are formed. Depending on application, the semiconductor substrate 101 may predominantly comprise suitably doped silicon in some examples, although other semiconductor materials such as, Ge, SiGe, GaAs, SiC, GaN, other Group III-V materials, etc., may be used in some implementations, where one or more epitaxial layers or single-crystal layers may be formed or provided in certain areas of the semiconductor substrate 101 in some arrangements.

The capacitor 102 includes a first electrode 104 and a second electrode 105. Without limitation, implied or otherwise, the first electrode 104 may be referred to as bottom plate/electrode or lower plate/electrode 104, and the second electrode 105 may be referred to as top plate/electrode or upper plate/electrode 105. In versions of some examples, the top plate 105 and the bottom plate 104 may have similar or identical form factors, e.g., having the same size, thickness, and shape, etc., although it is not a necessary requirement for purposes of the present disclosure. Further, in an example implementation, the bottom plate 104 may be disposed directly between the top plate 105 and the substrate 101 along a surface normal, e.g., with or without varying amounts of overlap between the two plates. The top plate 105 may be connected to a high-voltage circuit node, while the bottom plate 104 and the transistor 103 may be connected to a low-voltage circuit node in some arrangements.

In some examples, the bottom plate 104 and/or the top plate 105 may have a minimum length along a longest axis of about 30 μm. Likewise, the bottom plate 104 and/or the top plate 105 may each have a minimum length along an orthogonal shortest axis of about 30 μm. In some examples, each of the bottom plate 104 and the top plate 105 may have an aspect ratio (e.g., length of longest axis divided by length of orthogonal shortest axis) of in a range between about one and about five. The plates 104 and 105 are not limited to any particular shape, which may comprise a variety of geometrical shapes, e.g., squares, circles, ovals, ellipses, rectangles, ovoids, coils/serpentines, racetracks, obrounds, trapezoids, rhomboids, regular or irregular polygons, etc. In some further examples, the plates 104 and 105 may have a minimum lateral width (parallel to a major surface of the substrate 101) sufficient to facilitate the formation of a wire bond, e.g., bond 197, with respect to the top plate 105, in order to provide connectivity with external circuitry (not shown in this Figure). Such minimum width may depend on the wire bonding technology, and without any limitation, may be about 80 μm. In one non-limiting example, the plates 104 and 105 each have a short axis length of about 120 μm and a long axis length of about 160 μm. In another non-limiting example, the plates 104 and 105 are both of a circular shape, with a diameter of about 120 μm. In some examples, one of the bottom plate 104 and the top plate 105 may be implemented as a plurality of plates, e.g., two plates. Thus, in one non-limiting example, the bottom plate 104 may be a single continuous metal plate, while the top plate 105 may be two noncontiguous metal plates. In such examples, the two or more plates need not be a same shape, or have a same area.

The example of FIG. 1A-1 illustrates a five-level-metal (5LM) device 100, without any limitation thereto. The device 100 therefore includes five metal levels respectively designated as MET1 through MET5, Met1 through Met5, M1 through M5, or with terms of similar import. Each metal level includes metal features within a corresponding inter/intra-metal dielectric (IMD) layer IMD1-IMD5. An interlevel dielectric (ILD) layer is located between each IMD layer, such that there are four dielectric layers ILD1-ILD4 in the illustrative example of FIG. 1A-1. A pre-metal dielectric (PMD) layer 114, which may comprise one or more (sub) layers, is located between the IMD1 level and the substrate 101. In some arrangements, the PMD layer 114 may be comprise materials operable as a penetration barrier to various impurities created by one or more CMP or other processes that may be employed in the fabrication of the various MET layers and interconnecting vias operable to provide electrical connectivity between two or more MET layers disposed at different levels. Depending on implementation, example PMD materials may comprise, low-pressure tetra-ethyl-ortho-silicate glass (LP-TEOS), Si-rich (SR)-oxide, plasma-enhanced (PE)-oxynitride, PE-nitride, PE-TEOS films, etc., and may be doped with fluorine or phosphorous.

A passivation/protective overcoat (PO) layer 196 comprising one or more (sub) layers overlies the top metal layer MET5. Depending on implementation, the PO layer 196 may have a total thickness of several tens or hundreds of nanometers (nm) to several microns (μm) that may include one or more layers or sublayers of insulator materials such as, e.g., silicon nitride, silicon oxide, silicon oxynitride, polyimide, etc. that may be deposited as part of the BEOL process. In general, IC chips designed to operate with higher voltages may require thick PO layers, e.g., in a range from about 4 μm to about 10 μm.

A molding compound (not shown in FIG. 1A-1) provided to encapsulate the semiconductor device 100 in die form as part of a packaging body overlies the PO layer 196. In some arrangements, the packaging body may be formed by a thermoset epoxy resin in a molding process, or by the use of epoxies, plastics, or resins that are liquid at room temperature and are subsequently cured.

An optional isolation structure 106, e.g., a shallow trench isolation (STI) structure, may be disposed between the PMD layer 114, e.g., comprising (sub) layers 112, 115, and the substrate 101. In some examples, the isolation structure 106 may be operable to reduce capacitive coupling between the bottom plate 104 and the substrate 101. In other examples, not shown, the isolation structure 106, if present, may include one or more doped well regions that may provide junction isolation between the bottom plate 104 and the substrate 101. As depicted in FIG. 1A-1, the bottom plate 104 may be formed from a metallic structure disposed in the MET2 level of the illustrated 5LM metal interconnect example, but could be located in another metal level in other examples. The metal level in which the bottom plate 104 is located may be selected in part based on design considerations such as the desired isolation of the bottom plate 104 from the substrate 101, expected capacitive coupling to the top plate 105, etc.

The plates 104 and 105 may comprise any suitable metal. Examples described herein may describe the plates 104 and 105 as being formed from aluminum (Al), although other metal interconnect systems, such as copper (Cu) or gold (Au), may be used in additional and/or alternative arrangements without undue experimentation. The top plate 105 may be configured to receive a high voltage signal, e.g., via a wire ball-bonded to the top plate 105. The high voltage signal may be received from a high-voltage source to which the device 100 is connected, e.g., another IC operating in a high voltage domain, an electric motor, etc., to provide data transmission or an electronic function such as monitoring or controlling. Depending on implementation, “high voltage” may refer to a static or RMS voltage of about 100 V or more, and “low voltage” may refer to a static or RMS voltage of about 20 V or less for purposes of some examples herein, without limitation.

The top plate 105 is capacitively coupled to the bottom plate 104 through a dielectric stack comprising the intervening dielectric layers, e.g., ILD1-ILD4 and corresponding IMD1-IMD4 in the illustrated arrangement of FIG. 1A-1. The coupling may induce on the bottom plate 104 an attenuated electric signal corresponding to the high-voltage signal present at the top plate 105. The attenuated signal at the bottom plate 104 may be coupled to another electronic device on another semiconductor substrate, or may be routed to an electronic device located on the same substrate, such as the transistor 103.

In some examples, the plates 104 and 105 may be located between via stacks or columns, described further below, that connect to the substrate 101. The substrate 101 may provide a ground reference for the via stacks, e.g., such that the via stacks may provide a guard ring 109 operable as part of a Faraday cage capable of terminating or otherwise containing electric field lines associated with the plates 104 and/or 105. Further, the guard ring 109 provides an outer perimeter of a DTI volume over the substrate, where the DTI volume comprises various levels of dielectric layers in which one or more conductive posts may be positioned at locations relative to the bottom plate 104 and/or the top plate 105. In versions of this example, the conductive posts are operable to direct or otherwise effectuate discharge paths between the top plate 105 and the bottom plate 104, e.g., where a discharge path may be from the top plate 105 towards the bottom plate 104 or vice versa, rather than laterally though the polyimide/mold materials overlying and/or laterally adjacent to the isolation capacitor 102. Although a guard ring such as the guard ring 109 is illustrated in the example shown in FIG. 1A-1, it is not a necessary requirement for purposes of the present disclosure. In some arrangements, the guard ring 109, where provided, may be spaced apart from the plates 104 and 105 by a distance greater than a DTI thickness or a multiple of DTI thickness between the plates 104 and 105 in order to reduce or eliminate the risk of limiting the component's expected lifetime.

In general, conductive posts may be disposed between a bottom horizontal plane (e.g., a first X-Y plane) through the bottom plate 104 and a top horizontal plane (e.g., a second X-Y plane) through the top plate 105 at any location within a BEOL stack that facilitates a discharge path between the top plate 105 and the bottom plate 104 when the isolation capacitor 102 encounters a high electric field (e.g., caused by an out-of-specification voltage spike). As will be set forth further below, the conductive posts may be fabricated using an existing via formation stage in BEOL processing according to some examples, thus avoiding extra mask layers and associated manufacturing costs. Although a via formation stage may be advantageously leveraged to fabricate conductive posts operable as a discharge path direction mechanism with respect to the isolation capacitor 102, the conductive posts are not electrically connected between features of one interconnect level (e.g., metal interconnect structures such as a horizontal routing layer, etc.) and features of another interconnect level (e.g., metal interconnect structures such as a horizontal routing layer, etc.) of the multilevel metallization scheme, e.g., 5LM scheme, illustrated in FIG. 1A-1.

For purposes of some examples of the present disclosure, three types of silicon dioxide dielectric materials are described. Two types may be produced by a plasma-enhanced chemical vapor deposition (PECVD) process in a capacitively-coupled plasma reactor using tetraethoxysilane (TEOS) feedstock. These dielectrics are referred to herein as “PE-TEOS”, where a first type of PE-TEOS is a “high-stress” PE-TEOS and a second type of PE-TEOS is “low-stress” PE-TEOS, without limitation. In a non-limiting example, a “high-stress” PE-TEOS process may be configured to produce an SiO₂ layer with about −120 MPa (megapascal) compressive stress, whereas a “low-stress” PE-TEOS process may be configured to produce an SiO₂ layer with about −20 MPa compressive stress. A third type of silicon dioxide may be produced using by a high-density plasma in an inductively-coupled reactor, and is referred to as “HDP oxide”, without limitation. In some arrangements, HDP oxide and/or high-stress PE-TEOS may be used as the dielectric in close proximity to or in contact with the plates 104 and 105, while one or more of the dielectric levels between the plates 104 and 105 include low-stress PE-TEOS to reduce the impact/extent of wafer bow. Additional details with respect to forming PE-TEOS and HDP oxide layers that may be implemented in some examples of the present disclosure may be found in U.S. Pat. No. 11,495,658, which is incorporated by reference herein for all purposes.

Continuing to refer to the example of FIG. 1A-1, the PMD layer 114 is illustrated as a composite layer comprising layers 112, 115, where a phosphorous-doped silicate glass (PSG) material is used for forming layer 112 and a high-stress PE-TEOS material is used for forming layer 115, each having a suitable thickness depending on implementation. In some other examples, the PMD layer 114 may be undoped and formed from a single dielectric type. The specific selection of the PMD layer materials may depend on, e.g., the type and functionality of transistors included in the device 100. In some arrangements, the IMD1 layer may include an HDP oxide sublayer 121 and a high-stress PE-TEOS sublayer 127. Such a configuration may be produced by first depositing the HDP oxide sublayer 121 over MET1 features, with the MET1 features producing a topography in the HDP oxide sublayer 121. As used herein, the term “topography” may be defined as a deviation of the top surface of a material layer from planarity by at least 10% of the layer thickness within a lateral distance of three times the layer thickness. The high-stress PE-TEOS sublayer 127 of IMD1 is formed over the HDP oxide sublayer 121 and planarized to produce a suitable surface for subsequent processing as will be set forth further below. A high-stress PE-TEOS layer 130 is then formed as part of ILD1 over the planarized surface of the high-stress PE-TEOS sublayer 127.

In the illustrated example, the bottom plate 104 is formed in the MET2 level that is formed over the high-stress PE-TEOS sublayer 130, where an HDP oxide layer 139 is formed as part of the IMD2 layer over the bottom plate 104. Accordingly, the bottom plate 104 is bounded by HDP oxide on top and side surfaces, and by high-stress PE-TEOS on the bottom surface. The bottom plate 104 and the top plate 105 are spaced apart by a dielectric stack structure (e.g., forming a DTI structure) comprising portions of or formed from the various ILD and IMD layers, which may comprise PE-TEOS and/or HDP oxide materials. In some examples, a silicon nitride (SiN) layer forming part of the DTI structure may be formed directly underlying the top plate 105 for providing additional HV robustness, although it is not a requirement for purposes of the present disclosure.

In the illustrated example, portions of the ILD2, IMD3, ILD3, IMD4 and ILD4 layers may be operable as part of a vertical stack structure of dielectrics (not specifically labeled with a reference number in FIG. 1A-1) disposed between the bottom and top plates 104, 105, respectively. In some arrangements, the IMD2, IMD3 and IMD4 layers or levels may each include a respective PE-TEOS layer 141, 156, 171. The top plate 105 may be located at least partially within the IMD5 layer, which includes an HDP oxide layer 190, where the HDP oxide layer 190 covers or touches sidewalls and a portion of the top surface of the top plate 105 such that only an opening 199 formed for wire bonding is exposed. In similar fashion, a TEOS layer 193 having an opening corresponding to the wire bond opening of the HDP oxide layer 190 may be formed thereover. A suitable PO layer, e.g., PO layer 196, may be formed to cover remaining portions of the TEOS layer 193 of the IMD5 level. Additionally, the PE-TEOS layer 171 of IMD4 may be covered by a SiN layer 177 and an SiON layer 174 for enhancing HV breakdown performance of the electronic device 100 in some examples. In still further examples, the SiN layer 177 may comprise SiN sublayers 177A, 177B having different characteristics such as refractive indices, although it is not a requirement.

In some arrangements, the PE-TEOS layers 141, 156, 171 may be provided as low-stress layers that may be encapsulated by other dielectric layers that effectively prevent moisture diffusion into the dielectric stack and/or prevent significant out-diffusion of moisture incorporated in the PE-TEOS layers during manufacturing. In other examples, not shown, configured to operate in relatively low-voltage applications in which the risk of dielectric breakdown near corners of the top plate 105 is reduced, low-stress PE-TEOS layers may be replaced by high-stress PE-TEOS layer of similar thicknesses, respectively.

In the example of FIG. 1A-1, an oxide layer may be disposed in direct contact with one or more neighboring oxide layers. In other examples, a thin layer of a dissimilar dielectric may be placed between some neighboring oxide layers. By way of illustration, a nitrogen-containing dielectric such as SiN or SiON may be placed between a low-stress PE-TEOS layer and a high-stress PE-TEOS layer, or between a low-stress PE-TEOS layer and an HDP oxide layer. The dissimilar dielectric, if used, may be a thin layer, e.g., 30 nm to 300 nm, to minimize the contribution to the cumulative stress of the dielectric stack in some additional, alternative and/or optional arrangements. With respect to the particular 5LM device 100 shown in FIG. 1A-1, IMD1 is illustrated as layers 121, 127; ILD1 is illustrated as layer 130; IMD2 is illustrated as layers 139, 141; ILD2 is illustrated as layer 144; IMD3 is illustrated as layers 153, 156; ILD3 is illustrated as layer 159; IMD4 is illustrated as layers 168, 171; ILD4 is illustrated as SiN layer 177 and SiON layer 174; and IMD5 is illustrated as layers 190, 193. In some examples, optional isolation breaks or cutouts 180 in the SiON/SiN composite layer 174/177 may be provided in order to enhance lateral breakdown performance of the device 100, especially in applications involving 1000V or higher, as set forth in U.S. Pat. No. 9,299,697, which is incorporated by reference herein for all purposes. Further, reference numbers 124, 136, 150, 165, and 187 refer to various metal structures at MET1-MET5 levels, respectively. Additionally, contact vias 118 through PMD 114 as well as inter-level vias 133, 147, 162, and 183 through corresponding ILD1-ILD4 layers are illustrated in the example of FIG. 1A-1.

In the example shown in FIG. 1A-1, a conductive post 195A may be formed during the fabrication of inter-level vias 147 that connect between the metal structures 136 of the second metallization level, e.g., MET2, and the metal structures 150 of the third metallization level, e.g., MET3, where the conductive post 195A touches or directly contacts a top surface 191 of the bottom plate 104. Whereas only one conductive post 195A is shown that is positioned at or proximate to a center of the bottom plate 104, there could be a plurality of such conductive posts 195A that may be arranged in a grid, where the grid of posts may have a center (e.g., a geometric center or centroid of the grid's planar geometrical shape) that is co-aligned with a center (e.g., a geometric center or centroid) of the bottom plate 105, or laterally translated away from the center of the bottom plate 104. In some examples, the plural conductive posts 195A may be arranged in a 2×2 grid, 4×4 grid, or more generally, an N×M grid that may be constructed by a repetitive unit cell of a minimum dimensionality, etc., without limitation. In some examples, the conductive posts 195A may be arranged in configurations other than grids, arrays or matrices, e.g., single line formations such as rows or columns of variable length, in straight lines or in curvilinear shapes, or as circles, triangles, regular or irregular polygons, etc., which may be placed anywhere on the top surface 191 of the bottom plate 104. In some additional and/or alternative implementations, the conductive posts 195A, whether configured as an array or in a single curvilinear form, may be arranged closer to an edge of the plate 105 as will be seen further below.

In some examples, the posts 195A may have form factors similar to those of the inter-level vias 147 although it is not a requirement. The mask layer used for fabricating the inter-level vias 147 may be suitably modified to accommodate similar or different sizes for the posts 195A depending on implementation. In one example arrangement, the conductive posts 195A may comprise metallic posts (e.g., tungsten) having a height 194A in a range from about 2 μm to about 4 μm and having a width 198A in a range from about 0.5 μm to about 1.5 μm wide.

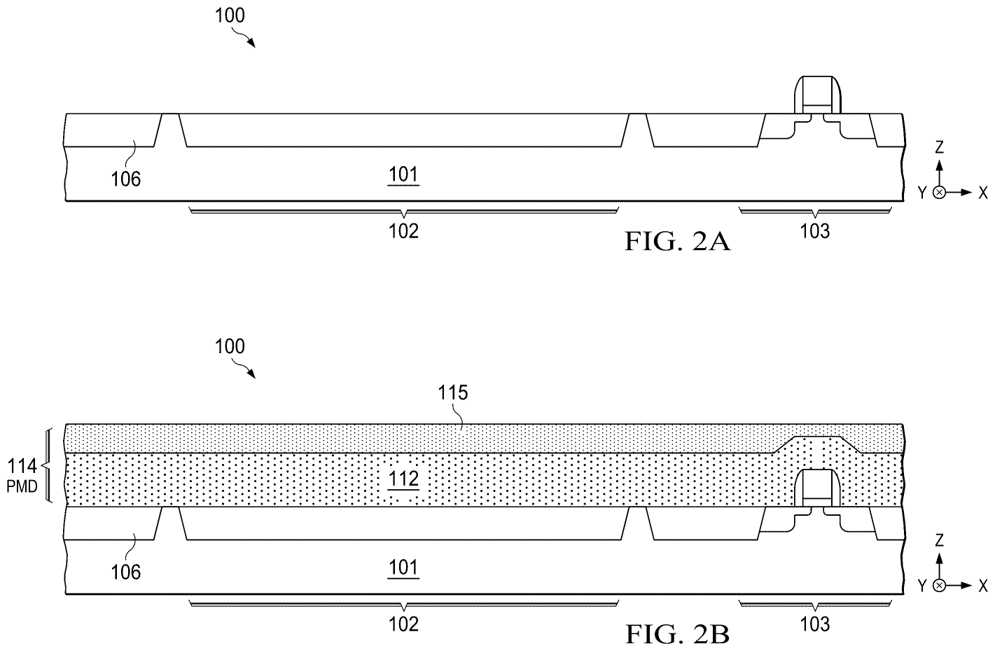

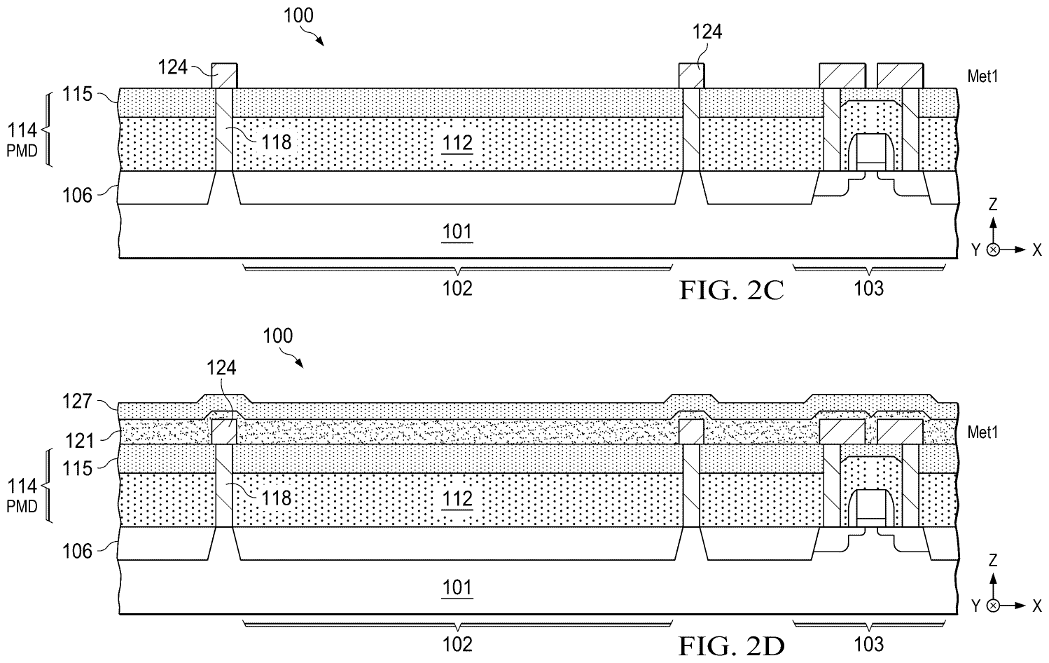

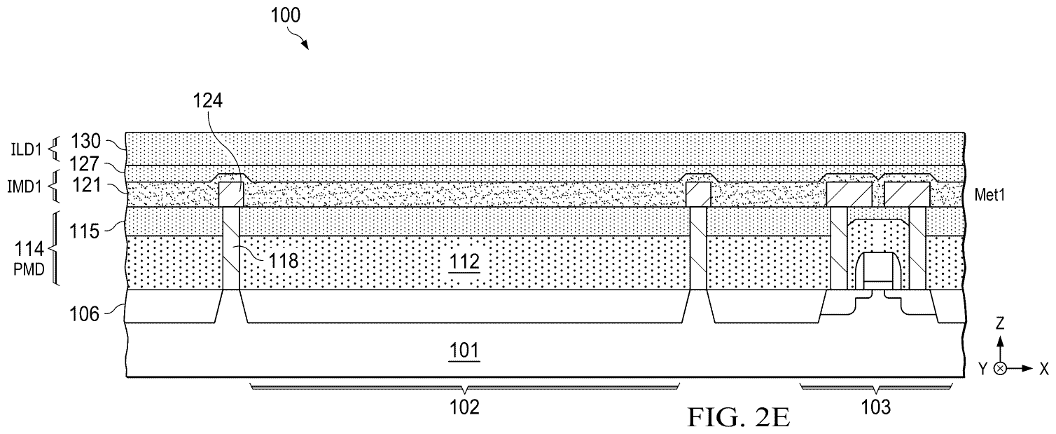

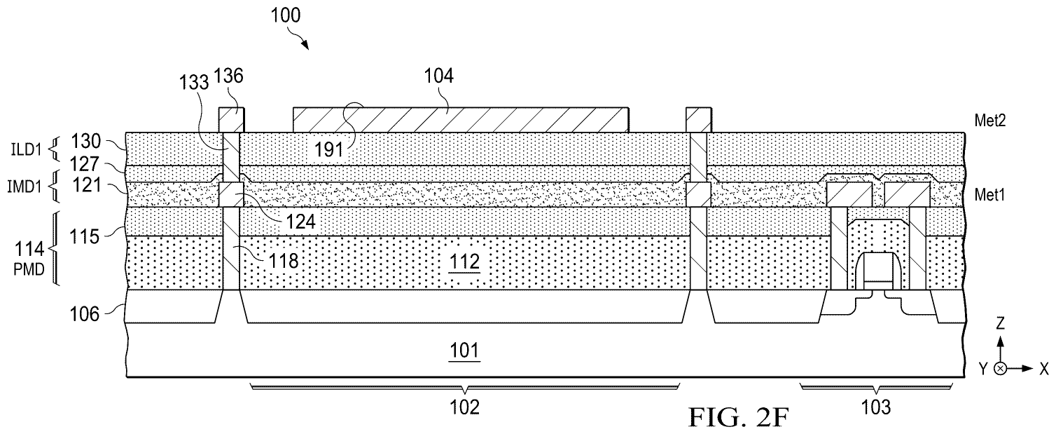

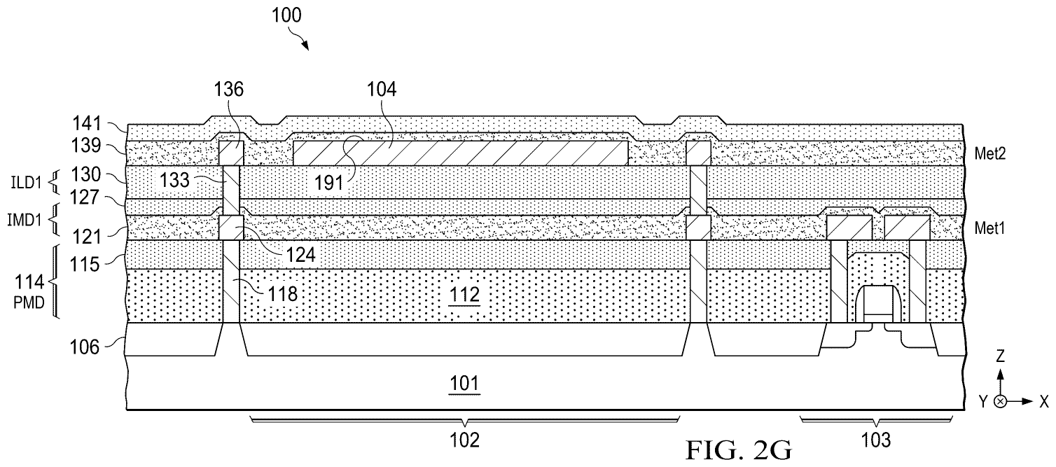

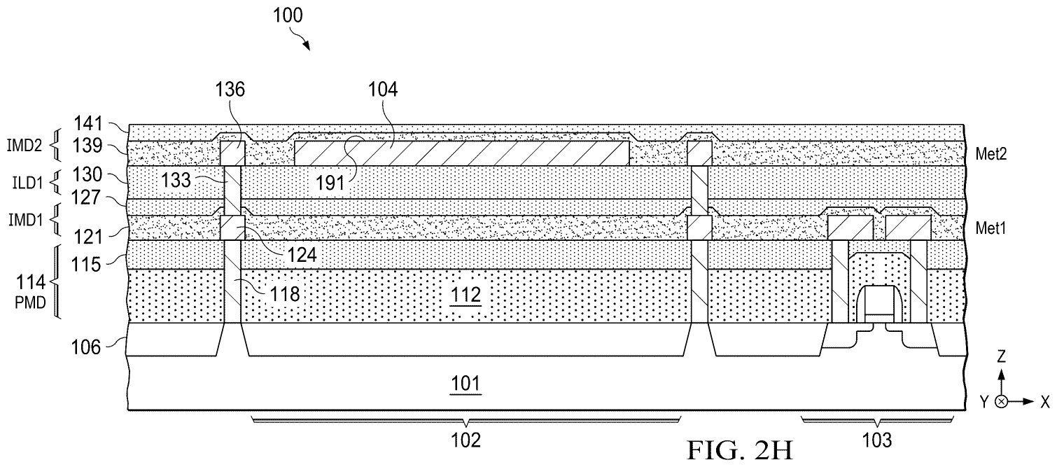

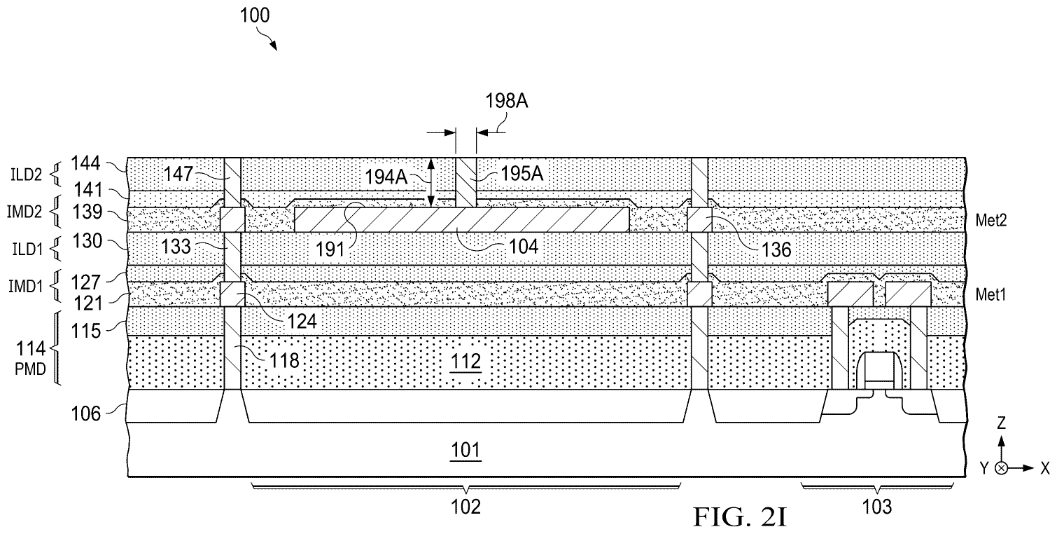

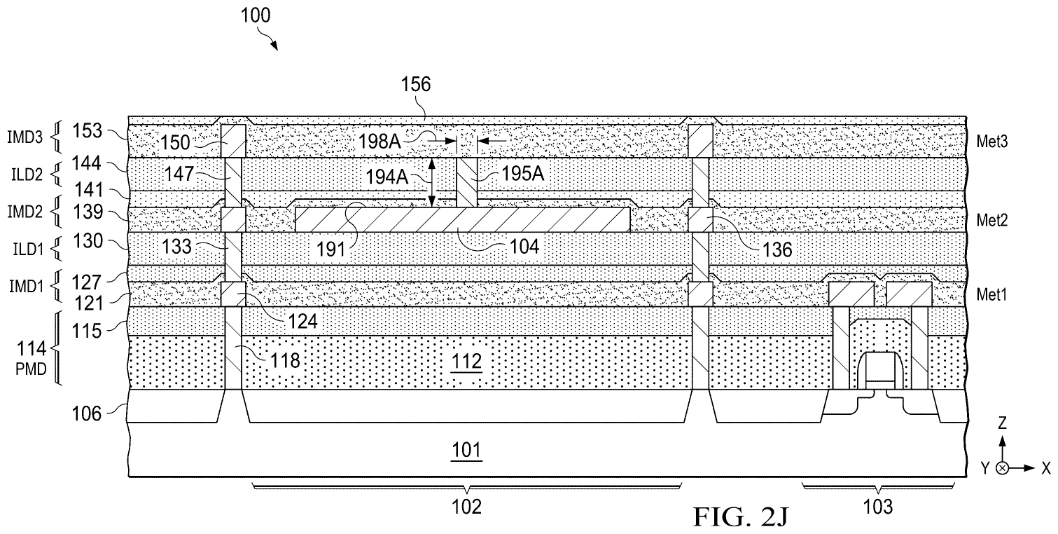

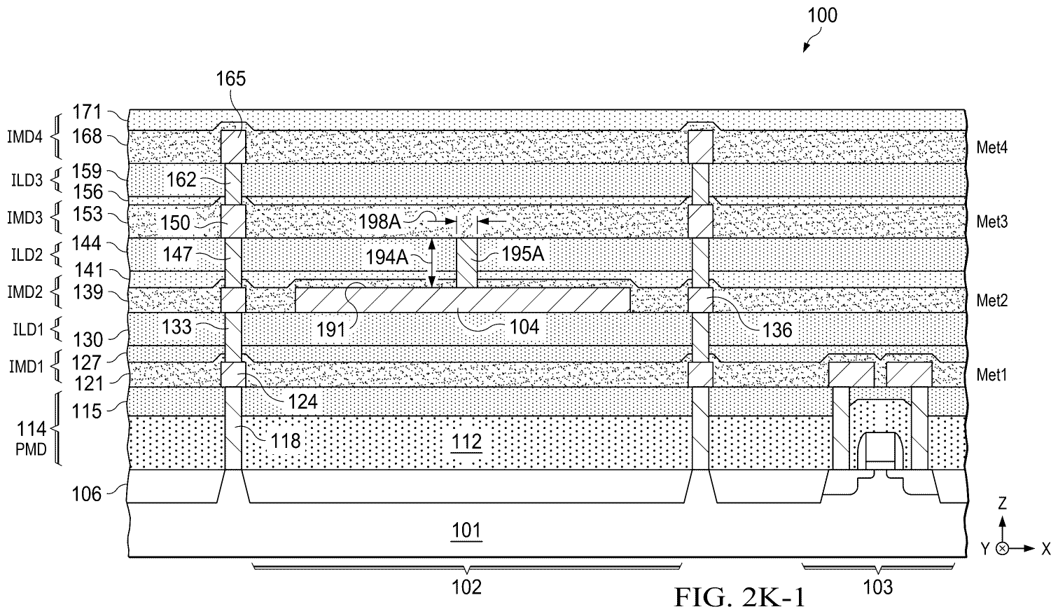

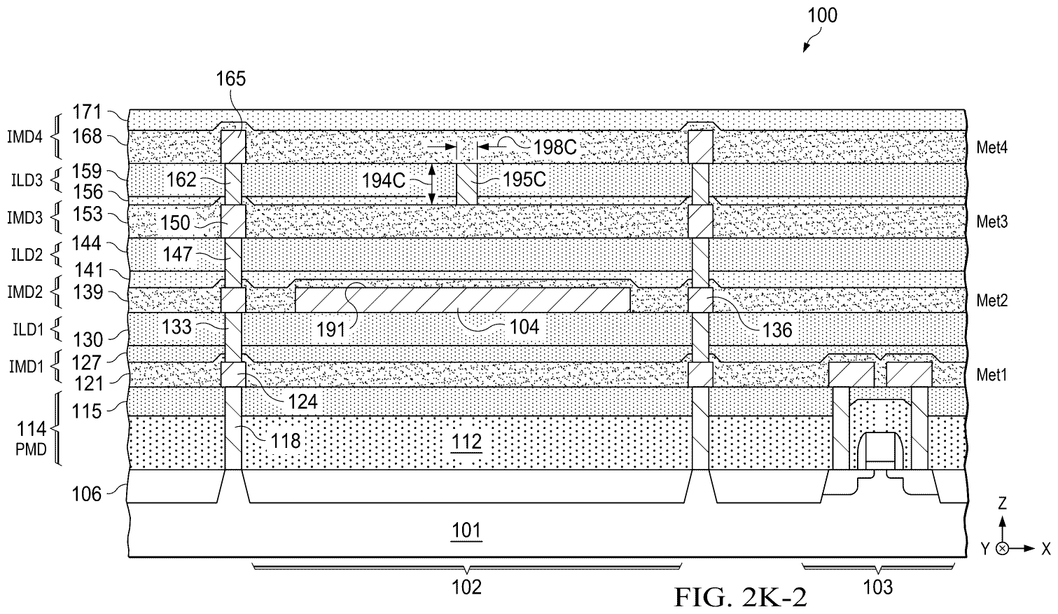

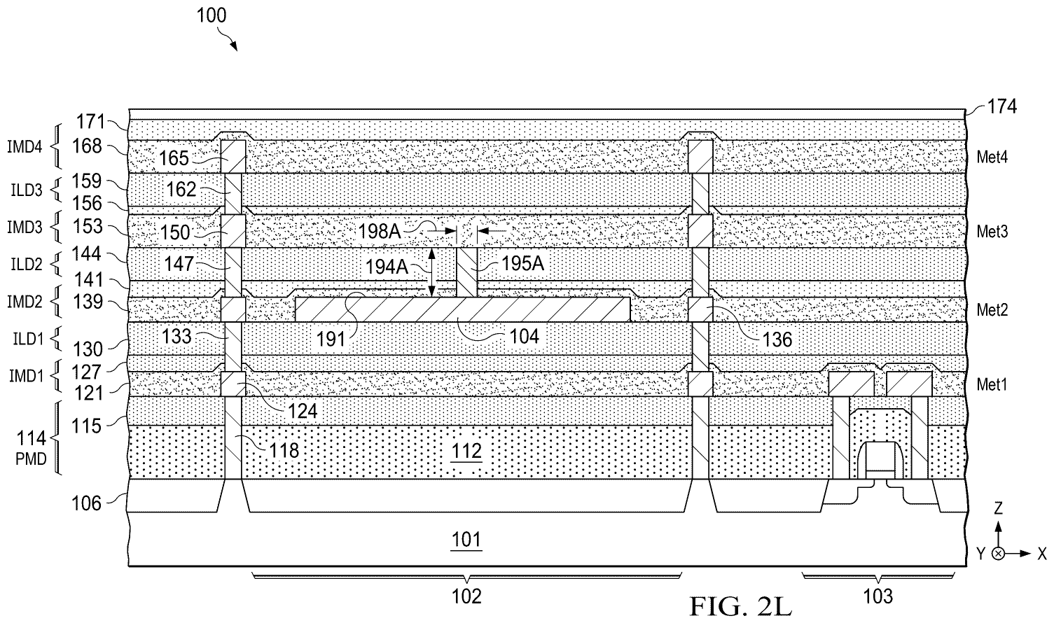

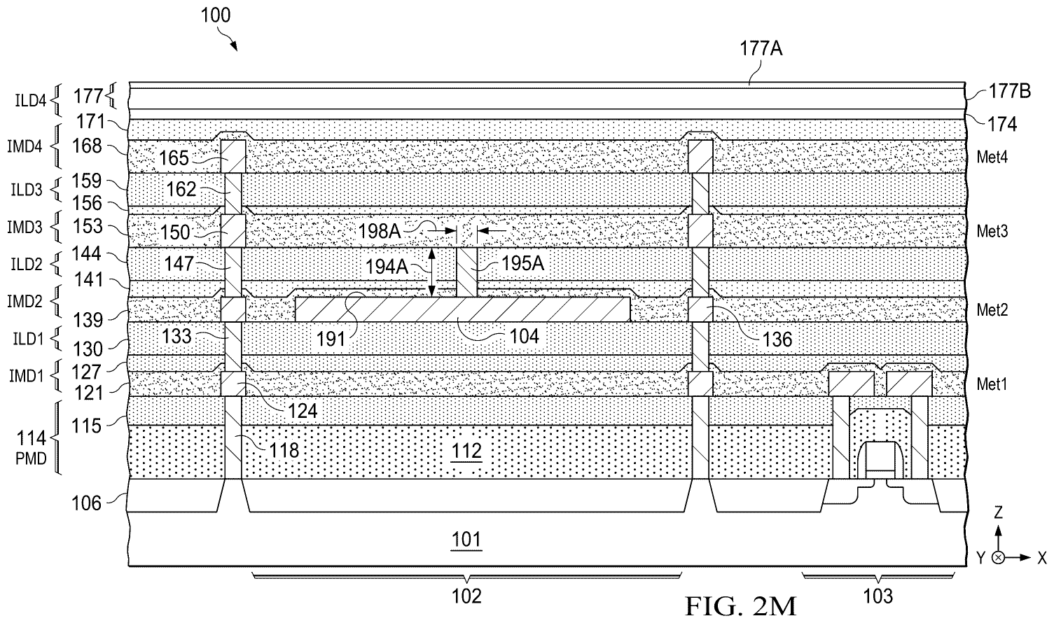

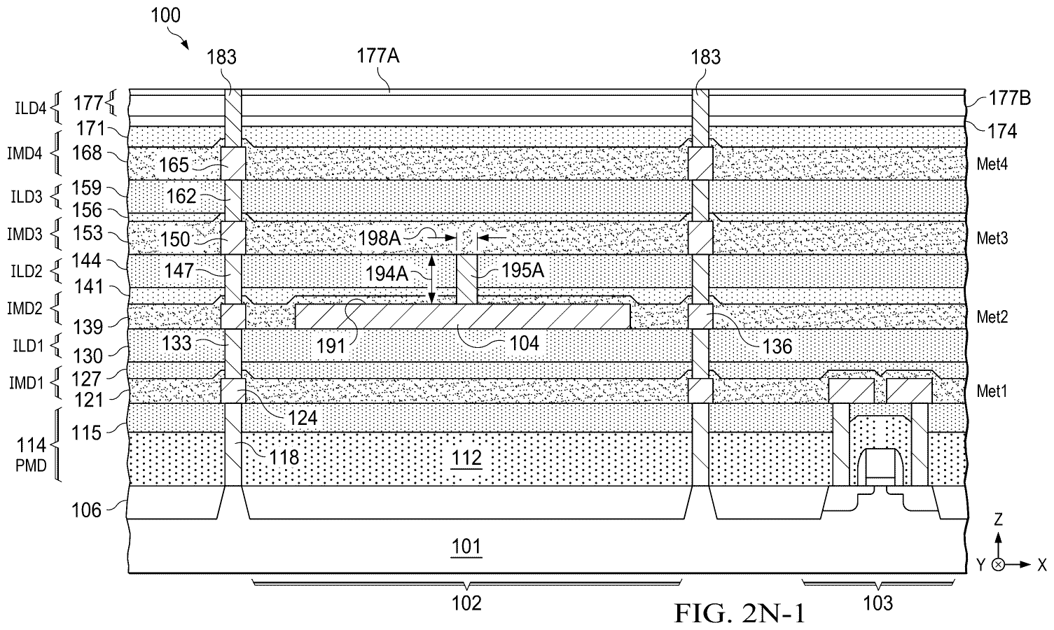

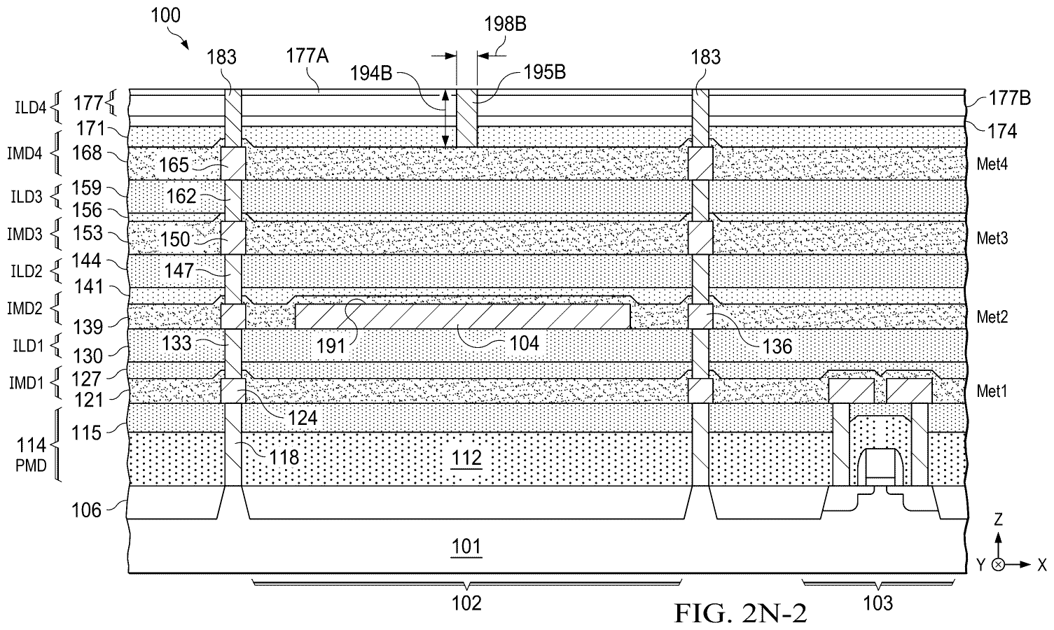

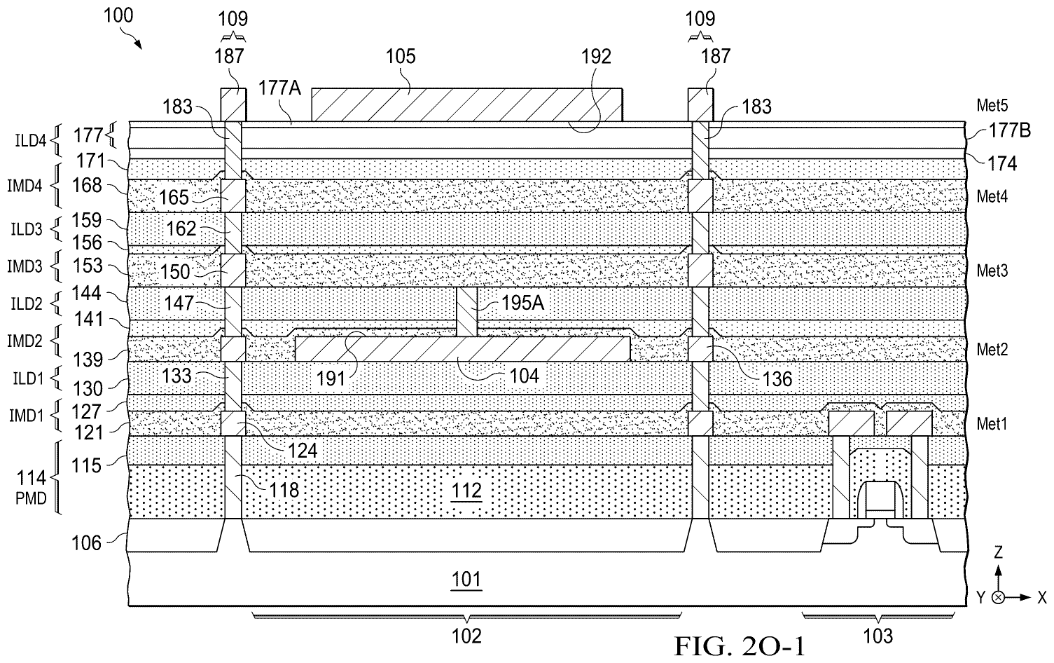

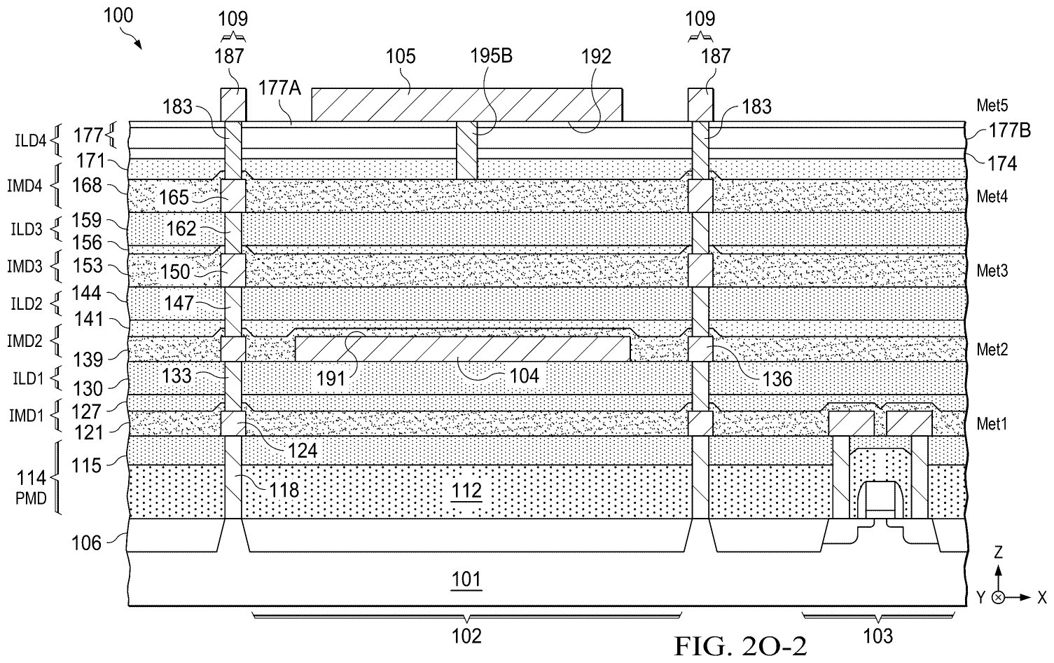

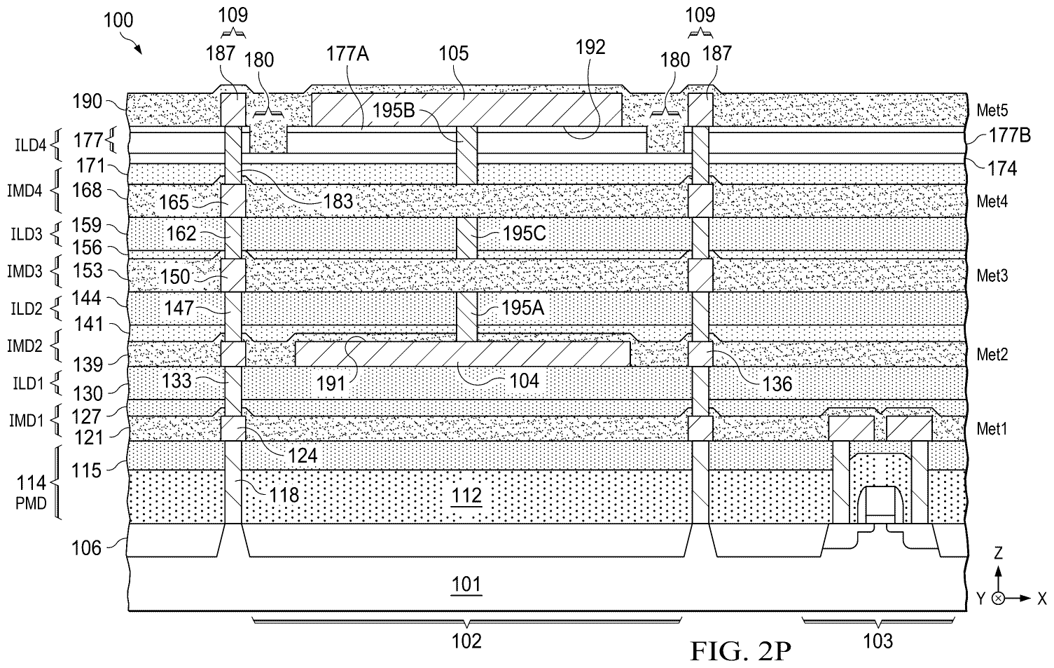

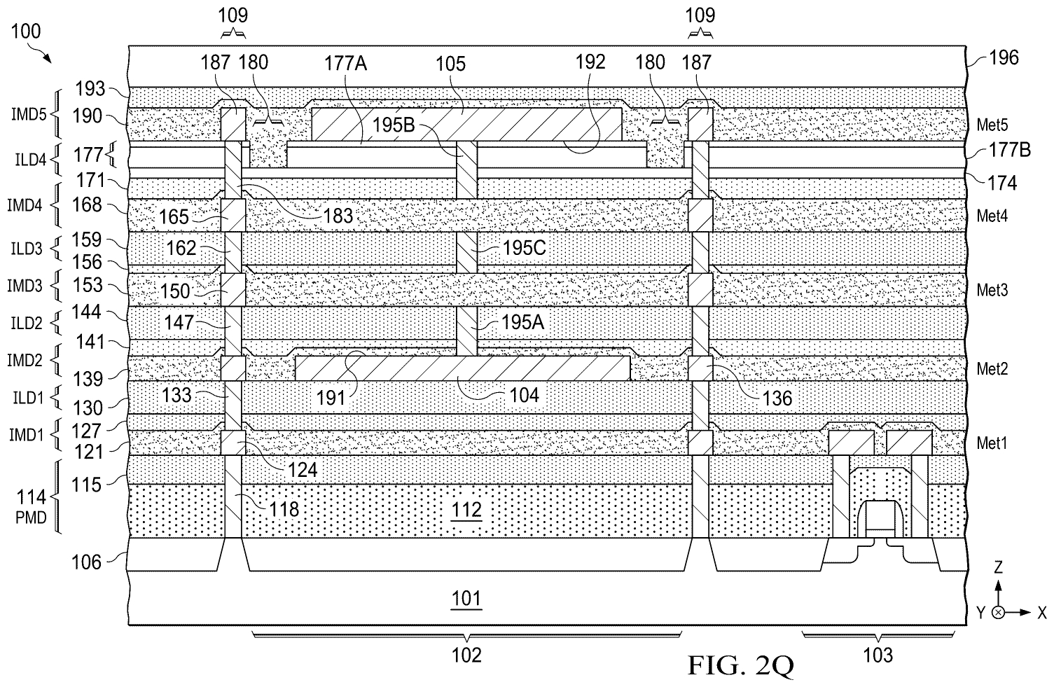

Analogous to the arrangement of conductive posts 195A contacting the top surface 191 of the bottom plate 104 set forth above, one or more conductive posts 195B touching a bottom surface 192 of the top plate 105 may be provided in some additional and/or alternative arrangements. A representative version of this example is shown in the sectional view of FIG. 1A-2. The sectional view of the semiconductor device 100 depicted in FIG. 1A-2 is identical to the sectional view depicted in FIG. 1A-1 except for the placement of the conductive posts 195B. Accordingly, the description of FIG. 1A-1 set forth above is equally applicable to FIG. 1A-2 and will not be repeated here except as otherwise noted.

In some examples, the conductive posts 195B may be formed during the fabrication of inter-level vias 183 that connect between the metal structures 165 of the fourth metallization level, e.g., MET4, and the metal structures 187 of the fifth metallization level, e.g., MET5, where the conductive posts 195B are configured to contact the bottom surface 192 of the top plate 105. Further, the conductive posts 195B may extend downward to the interface of the layers 171 and 168. Depending on the via etch process implemented, and because there is no landing metal structure such as the structure 165 stopping the etch, the conductive posts 195B may extend through the interface of the layers 171 and 168 in some versions of this example, although not specifically shown in FIG. 1A-2. Similar to the conductive posts 195A, the conductive posts 195B may comprise any number and/or configuration, and may be placed anywhere on the bottom surface 192 of the top plate 105. Further, the conductive posts 195B may have a height 194B and a width 198B similar to the height 194A and width 198A of the conductive posts 195A, although it is not a requirement.

In some examples, one or more conductive posts may be formed during the fabrication of inter-level vias that are not associated with the metal levels corresponding to the bottom plate 104 and/or the top plate 105 of the isolation capacitor 102. In such arrangements, the conductive posts are electrically isolated from both the bottom plate 104 and the top plate 105, and may be formed in any intervening dielectric layer as “floating” posts. By way of illustration, one or more conductive posts 195C may be formed in ILD3 during the fabrication of the inter-level vias 162 as shown in FIG. 1A-3, where the inter-level vias 162 connect between the metal structures 150 of the third metallization level, e.g., MET3, and the metal structures 165 of the fourth metallization level, e.g., MET4. As with the bottoms of the conductive posts 195B, bottoms of the conductive posts 195C may extend through the interface of layers 156 and 153 in some examples due to the absence of a landing metal structure for stopping the via etch process. The sectional view of the semiconductor device 100 depicted in FIG. 1A-3 is identical to the sectional views depicted in FIGS. 1A-1 and 1A-2, respectively, except for the placement of the conductive posts 195C. Accordingly, the description of FIG. 1A-1 set forth above is equally applicable to FIG. 1A-3 and will not be repeated here except as otherwise noted where applicable.

Similar to the conductive posts 195A and 195C, the conductive posts 195C may comprise any number and/or configuration. Further, the conductive posts 195C may be formed anywhere in ILD3, e.g., within a boundary defined by a ground ring where provided, e.g., the guard ring 109. In some arrangements, the conductive posts 195C may have a height 194C and a width 198C analogous to the conductive posts 195A and 195B, although it is not a requirement.

In the examples of FIGS. 1A-1 through 1A-3, the conductive posts 195A, 195B and/or 195C (collectively “conductive posts 195”) are connected to another metal feature, such as the capacitor plates 104, 105 at no more than one surface, or none at all (e.g., “floating”). Thus the conductive posts 195 can carry no current except in the event of breakdown of one or more of the dielectric layers between the plates 104, 405. In particular, while the conductive posts 195 may be formed by a process that produces vias such as the vias 133, 147, 162, and 183, the conductive posts 195 carry no current between interconnect levels, and do not conduct current in any circuit node except during a discharge event.

In some additional and/or alternative examples, more than one configuration of conductive posts may be provided, e.g., by employing different combinations of plate-connected posts such as the posts 195A and 195B as well as floating posts such as the posts 195C. In still further arrangements, the conductive posts 195A and/or the conductive posts 195B may be “decoupled” from respective plates 104, 105, where the posts 195A and 195B may be fabricated as floating posts anywhere in ILD2 and ILD4, respectively, but bounded by the guard ring 109 if provided. Accordingly, the examples herein may be combined in myriad permutations and combinations, coupled with different selections of the number of conductive posts, form factors and/or grid configurations, to achieve a highly customizable discharge path direction mechanism for a galvanic isolation component depending on the HV application environment.

Turning to FIG. 1B, depicted therein is a top plan view of the device 100 along the plane X′-X″ in MET5 level shown in FIGS. 1A-1 through 1A-3. By way of illustration, a single conductive post 195 representative of the conductive posts 195A-195C is shown in FIG. 1B. Whereas the conductive post 195 is representatively shown as being positioned interiorly with respect to the plates 104 and/or 105, examples of the present disclosure are not limited thereto. Depending on design considerations, the placement of conductive posts 195 may be determined based on where high field regions may be experienced and/or expected relative to the HV isolation capacitor 102 in an application environment. In some examples, high field regions may be more prevalent nearer to an edge of the plates 104 and/or 105 of the HV isolation capacitor 102. Accordingly, the conductive posts 195 may be positioned proximate to the edge of the plates 104 and/or 105 in some examples regardless of the shape or size of the plates 104 and/or 105 as set forth further below. In some arrangements, the HV isolation capacitor 102 may be provided as having a racetrack or an obround shape, where an opening of suitable size and shape, e.g., opening 199, overlying the top plate 105 and through a topmost IMD sublayer, e.g., layer 190 of IMD5, is illustrated. A vertical cross-section along a normal plane Y′-Y″ orthogonal to a horizontal plane of the device 100, e.g., the layer 190, yields sectional views such as the views described above in detail in reference to FIGS. 1A-1 through 1A-3 depending on where the conductive post 195 is positioned.

FIGS. 2A-2Q illustrate sectional views of the semiconductor device 100 at successive stages of manufacturing with respect to the examples of FIGS. 1A-1 to 1A-3, where most of the stages are common except for the stages at which the three types of conductive posts illustrated in FIGS. 1A-1 to 1A-3 are formed according to some examples herein. Accordingly, the description set forth below is broadly applicable to the arrangements of FIGS. 1A-1 to FIGS. 1A-3 except otherwise noted. In FIG. 2A, the substrate 101 is shown with the transistor 103 having been formed, where the location of the capacitor 102 is shown for reference. As described previously, one or more isolation structures 106 may be formed in the substrate 101 relative to the capacitor 102 and other circuit components, e.g., transistor 103. Further, where some examples do not include the transistor 103 or other circuitry, such examples are illustrative of an arrangement where the capacitor 102 may be referred to as a “standalone” capacitor in a discrete semiconductor device configuration. As noted previously, the substrate 101 may be any suitable substrate, e.g., semiconducting or insulating. In some examples, the substrate 101 is a silicon wafer or a portion of a silicon wafer (e.g., a semiconductor die), and may be doped with suitable dopants, e.g., p-type dopants.

FIG. 2B is representative of a stage where the PMD layer 114 has been formed. In the illustrated example, shown without limitation, a dielectric layer 112 is formed over the substrate 101, which projects a vertical and/or conformal topography above the transistor 103. The dielectric layer 112 may be a PSG layer, as noted previously. As shown in FIG. 2B, a dielectric layer 115 of high-stress PE-TEOS may be formed over the dielectric layer 112 and planarized to reduce the topography. In other examples, such as when the device 100 is a standalone device, an undoped dielectric may be used for the dielectric layer 112, e.g., high-stress PE-TEOS, and planarization may be omitted. In such examples, a SiN layer with a compressive stress of about −100 MPa may be used for the layer 115.

In FIG. 2C, contacts 118, e.g., comprising tungsten plugs, formed through the dielectric layers 112 and 115 are operable to contact the substrate 101 in the region of the capacitor 102. Additional unreferenced contacts may be provided for effectuating connectivity with respect to other components of the device 100, e.g., source/drain regions of the transistor 103. A metal layer may be formed over the dielectric layer 115 and patterned to form metal structures 124 connected to the contacts 118, and unreferenced interconnects connected to the source/drain contacts of the transistor 103. Example metal structures 124 may operate as a landing pad for a subsequent via in the corresponding via stack (as illustrated in FIGS. 1A-1 to 1A-3) or may form a closed loop with a corresponding other of the metal structures 124. The metal layer from which the metal structures 124 are formed may be an Al layer, without limitation, and the patterning may include baseline lithography and metal etch processes.

FIG. 2D illustrates the partially formed device 100 after deposition of a first IMD layer. An HDP oxide layer 121 of appropriate thickness may be formed initially. In some examples, HDP oxide may be preferred when spacing between the metal structures 124, or other metal features outside the view of the Figure, is small enough that PE-TEOS may not effectively fill the space. In other examples with more relaxed spacing, PE-TEOS may be used instead. In the illustrated example, a dielectric layer 127 of high-stress PE-TEOS is formed over the HDP oxide layer 121. Topography associated with the metal structures 124 may extend to the surface of the PE-TEOS layer 127, which may be planarized using suitable process, e.g., CMP, in order to remove a portion of the PE-TEOS layer 127, thus reducing the surface topography. FIG. 2E shows the device 100 after planarization of the PE-TEOS layer 127 and deposition of a PE-TEOS layer 130 on the planarized surface. The HDP oxide layer 121 and PE-TEOS layer 127 are designated IMD1, and the PE-TEOS layer 130 is designated ILD1 as previously noted. In another example, not shown, the PE-TEOS layer 127 may be deposited with a sufficient thickness to act as both the upper portion of the IMD1 level and as the ILD1 level, with the surface of the single PE-TEOS layer then planarized. This alternative implementation may be appropriate in certain examples based on an aspect ratio associated with the metal structures 124.

FIG. 2F illustrates the device 100 after forming vias 133 within ILD1, e.g., using tungsten (W) metallurgy, followed by forming a MET2 layer over the PE-TEOS layer 130 and patterning the MET2 layer to produce the bottom plate 104 having a top surface 191 and MET2 structures 136. Vias 133, formed within ILD1, are operable to connect the MET2 structures 136 to the MET1 structures 124. Similar to the MET1 level, the MET2 layer may be formed from Al. Depending on implementation, the MET2 structures 136 may follow a layout similar to that of the MET1 structures 124.

FIG. 2G illustrates the stage where an HDP oxide layer 139 and a PE-TEOS layer 141 have been formed over the bottom plate 104. The topography of the PE-TEOS layer 141 surface conforms to the underlying MET2 structures 136 and bottom plate 104. Thus, a CMP process may also be used at this stage to reduce the surface topography. FIG. 2H illustrates the device 100 after planarization of the PE-TEOS layer 141. The HDP oxide layer 139 and remaining PE-TEOS layer 141 may be designated IMD2 as previously noted.

FIG. 2I illustrates the device 100 after forming the PE-TEOS layer 144, where vias 147 for connecting MET2 structures 136 with MET3 structures 150 (shown in FIG. 2J) may be formed using suitable metallization processes and metallurgies, e.g., Al, Cu, W, etc. The PE-TEOS layer 144 is designated ILD2 in the examples herein. During the fabrication of the vias 147 through dielectric layer 144 and remaining portions of dielectric layers 141, 139, one or more conductive posts 195A are also formed using the via mask layer and metallurgy, where the conductive posts 195A having a height 194A and a width 198A contact the top surface 191 of the bottom plate 104 as noted previously with respect to the example of FIG. 1A-1. In some versions of this example, form factors and metallurgies different from the form factors and metallurgies of the vias 147 may be provided for the conductive posts 195A using extra mask layers, which may increase the manufacturing cost.

FIG. 2J illustrates the stage where another metallization level, e.g., MET3, having metal structures 150 is formed over the planarized surface of ILD2, where an HDP oxide layer 153 and a PE-TEOS layer 156 are provided as IMD3. Similar to the formation of lower levels, the surface of the PE-TEOS layer 156 may be planarized. The sequence of manufacturing steps used to produce the ILD2 and IMD3 as well as the vias 147 and MET3 structures 150 may be repeated as needed to provide a desired distance (e.g., DTI) between the bottom plate 104 and the top plate 105. Suitable adjustments may be made to accommodate metal spacing and thickness as well as any requirements imposed by baseline and/or qualified processes in a particular manufacturing facility.

In FIG. 2K-1, the formation of a fourth metallization level, e.g., MET4, having metal structures 165 is shown. In this example, a PE-TEOS layer 159 is formed over planarized PE-TEOS layer 156, followed by an HDP oxide layer 168 and another PE-TEOS layer 171. MET4 structures 165 are located within the HDP oxide layer 168, where vias 162 through dielectric layer 159 and remaining portions of dielectric layers 153, 156 are formed to connect the MET4 structures 165 to the MET3 structures 150. As previously noted, the PE-TEOS layer 159 is designated ILD3 and the HDP oxide layer 168 and low-stress dielectric layer 171 are designated IMD4.

Whereas the example shown in FIG. 2K-1 is representative of the arrangement of FIG. 1A-1, FIG. 2K-2 depicts an example of the arrangement of FIG. 1A-2 where one or more floating conductive posts, e.g., the conductive post 195C, are fabricated through the layers 156 and 159 during the formation of the vias 162. Similar to the fabrication of the conductive posts 195A, the conductive posts 195C having a height 194C and a width 198C may be fabricated using the via mask layer and metallurgy used for fabricating the vias 162, although it is not a necessary requirement for purposes of some examples. As shown, the stage of FIG. 2K-2 follows the stages of FIGS. 2H-2J while omitting the formation of the conductive posts 195A.

In FIG. 2L, a SiON layer 174 is formed over the PE-TEOS layer 171 as part of a composite dielectric layer to underlie a top electrode for improving the HV breakdown performance of the capacitor structure to be formed. In some arrangements, the thickness and compressive stress of the SiON layer 174 may be matched, balanced or otherwise optimized relative to and/or in view of the subsequent formation of a SiN layer, which may be a bilayer in some arrangements as previously noted. Depending on implementation, various techniques and processes may be used for forming an SiON layer, e.g., thermal CVD or plasma-enhanced CVD, thermal atomic layer deposition (ALD) or plasma-enhanced ALD (PEALD), etc., using precursors and reactants such as silane (SiH₄), hexamethyldisilazane (HMDS), ammonia (NH₃), nitrous oxide (N₂O), oxygen (O₂), etc.

A SiN layer 177, e.g., comprising a lower SiN layer 177B and an upper SiN layer 177A in some examples, may be formed, resulting in a structure as shown in FIG. 2M. In some arrangements, the upper SiN layer 177A and the lower SiN layer 177B may each have respective RI characteristics, e.g., the upper SiN layer 177A having a lower RI than the lower SiN layer 177B, although it is not a requirement. Regardless of whether a bilayer arrangement is provided, the SiN layer 177 may have an overall target thickness, e.g., around 500 nm to 800 nm, depending on the HV application. Similar to the formation of the SiON layer 174, various techniques and processes may be used for forming the SiN layers 177A, 177B that may be suitably varied or modulated to achieve desired properties.

In FIG. 2N-1, vias 183 may be formed through the composite SiON/SiN layer 174/177 as well as remaining portions of dielectric layers 171/168. In an alternative and/or additional arrangement, one or more conductive posts 195B having a height 194B and a width 198B may be fabricated using the via mask layer and metallurgy used for fabricating the vias 183, resulting in a partially formed structure shown in FIG. 2N-2 that is representative of the arrangement of FIG. 1A-3, where the bottoms of the conductive posts 195B may extend through the interface between 171 and 168 in some examples as previously noted.

As set forth previously, the composite SiON/SiN layer 174/177 may be operable as ILD4 in an example arrangement. Vias 183, e.g., tungsten, extending through the ILD4 are operable to connect MET4 structures 165 to upper MET5 structures 187 that may be formed at a subsequent stage. FIG. 2O-1 depicts a fabrication stage where a top plate 105 has been formed as part of MET5 processing, which may include the formation of MET5 structures 187. In some optional examples, one or more isolation breaks or cutouts 180 may be formed in ILD4 (not specifically shown in FIG. 2O-1) after the formation of the top plate 105 to further improve lateral HV breakdown performance of the device 100 as previously noted.

Whereas the partially formed structure shown in FIG. 2O-1 is representative of the arrangement of FIG. 1A-1, FIG. 2O-2 depicts a partially formed structure representative of the arrangement of FIG. 1A-3, after the fabrication of the conductive posts 195B as set forth above in reference to FIG. 2N-2. The formation of the top plate 105 in FIG. 2O-2 accordingly results in in the conductive posts 195B touching a bottom surface 192 of the top plate 105.

FIG. 2P depicts a fabrication stage where the optional cutouts 180 have been formed in ILD4 of the device 100. Further, the arrangement of FIG. 2P depicts all three types of conductive posts, e.g., plate-coupled posts 195A, 195B and floating posts 195C, as an illustrative example, although any combination of posts 195A-195C may be provided in a particular implementation. Further, the posts 195A and 195B may be positioned closer to the edge of the respective capacitor plates 104 and/or 105 in some examples as set forth elsewhere in the present disclosure. In some arrangements, the optional cutouts 180 formed in ILD4 may operate to restrict dielectric breakdown paths between the top plate 105 and the guard ring 109. After forming the top plate 105, and optionally the cutouts 180, an HDP oxide layer 190 is formed over the top plate 105 and filling the cutouts 180, as shown in FIG. 2P. In FIG. 2Q, a TEOS layer 193 has been formed over the HDP oxide layer 190 and planarized, and a PO layer 196 has been formed over the TEOS layer 193. The PO layer 196 may have a compressive stress of about −160 MPa to about −180 MPa in some examples, without limitation. A wire bond opening, e.g., opening 199, may be formed over the top plate 105 by suitable patterning techniques, for connecting with a bond wire, resulting in a device arrangement as illustrated in FIGS. 1A-1 to 1A-3, respectively.

The preceding description of an example 5 LM process sequence including the fabrication of conductive posts is not limited to any particular thicknesses of metal and/or dielectric layers. Further, a similar process sequence for fabricating conductive posts may be provided in conjunction with any multilevel metal interconnect system having an arbitrary number of metallization levels (e.g., 6 to 12 MET levels or more), where the conductive posts may be provided at different levels to direct a discharge between the top plate/electrode and the bottom plate/electrode of an isolation device in the event of dielectric breakdown.

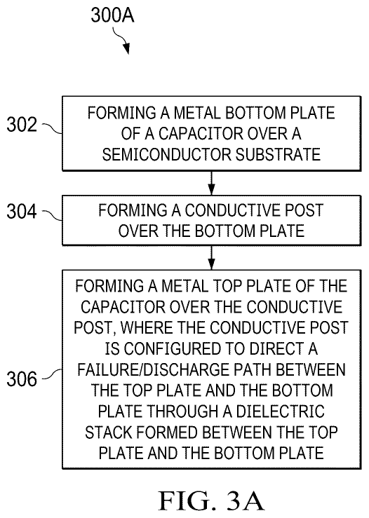

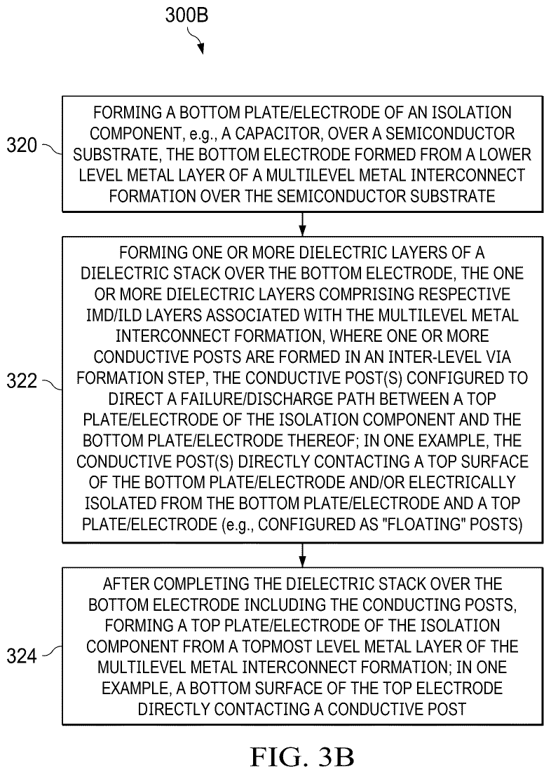

FIGS. 3A and 3B are flowcharts relating IC fabrication methods according to some examples of the present disclosure. In one arrangement, a method 300A shown in FIG. 3A may commence with forming a bottom metal plate of an isolation component, e.g., a capacitor, over a semiconductor substrate, as set forth at block 302. Depending on BEOL implementation, the bottom electrode may be formed from a lower level metal layer (e.g., MET2 level shown in FIG. 2F) of a multilevel metal interconnect (MMI) formation over the semiconductor substrate, as set forth previously. At block 304, one or more conductive posts may be formed over the bottom plate, which relates to some of aspects shown in FIG. 2I through FIG. 2N-2. At block 306, a top metal plate of the capacitor may be formed over the conductive posts, where the conductive posts extend or are otherwise disposed between the bottom plate and the top plate, which relates some aspects shown in FIGS. 2O-1 and 2O-2. As set forth previously, the conductive posts may be configured in numerous ways, e.g., contacting the bottom and/or top metal plates, unconnected to any interconnect structures of the MMI formation, etc., where the conductive posts are operable or otherwise configured to direct an electrical discharge between the top metal plate and the bottom metal plate through a dielectric stack formed between the top and bottom metal plates.

Method 300B shown in FIG. 3B may commence with forming a bottom electrode of an isolation component, e.g., a capacitor, over a semiconductor substrate, the bottom electrode formed from a lower level metal layer of an MMI formation over the semiconductor substrate as set forth at block 320, which is roughly analogous to block 302 above. At block 322, one or more dielectric layers of a dielectric stack may be formed over the bottom electrode, where the one or more dielectric layers comprise respective IMD/ILD layers associated with the MMI formation. In some arrangements, one or more conductive posts are formed in an inter-level via formation step, where the conductive post(s) are operable or otherwise configured to direct a failure path between a top electrode and the bottom electrode of the isolation component as further set forth at block 322. In one example, the conductive posts may directly contact a top surface of the bottom electrode. In one example, the conductive posts are electrically isolated from any interconnect structures of the MMI formation (e.g., configured as floating posts). After completing the formation of the dielectric stack over the bottom electrode including the conducting posts, a top electrode of the isolation component may be formed from a topmost level metal layer of the MMI formation as set forth at block 324. In one example arrangement, a bottom surface of the top electrode may directly contact the conductive posts as previously noted.

An example application where an IC die including capacitive isolation in association with conductor posts for discharge path direction is set forth below in the context of a packaged device implementation.

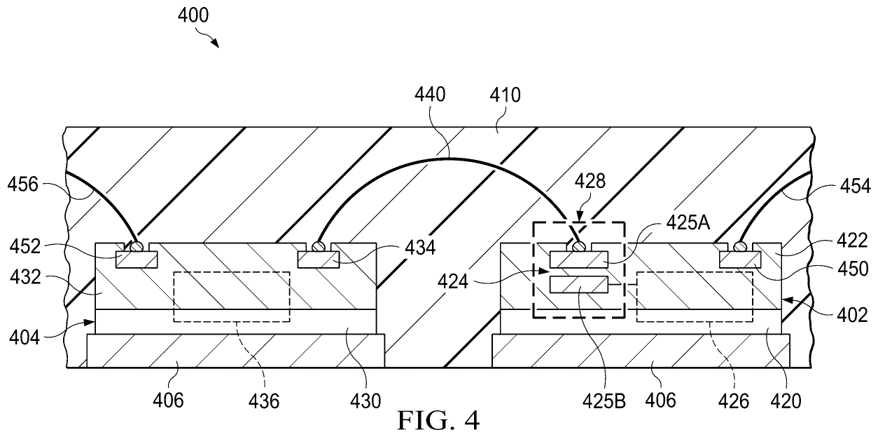

FIG. 4 is a partial cross-sectional view of an IC package 400 according to some examples. The IC package 400 includes a first IC die 402 and a second IC die 404, where the first IC die 402 and the second IC die 404 are attached to a leadframe portion 406, e.g., by an adhesive. A molding compound 410 encapsulates the first IC die 402 and the second IC die 404 on leadframe portion 406, forming a body of the IC package 400.

The first IC die 402 includes a semiconductor substrate 420 and a metallization structure 422 over the semiconductor substrate 420. In some examples, the IC die 402 may be representative of the semiconductor device 100 shown in FIGS. 1A-1 to 1A-3. The semiconductor substrate 420 may comprise any semiconductor material and can include a bulk material (e.g., bulk silicon) and one or more epitaxial layers of a semiconductor material. The metallization structure 422 may include multiple ILD layers and metal levels previously noted. The metallization structure 422 of the first IC die 402 includes a capacitor 424, which may be a galvanic isolation capacitor. The capacitor 424 includes a capacitor bottom plate 425B disposed in one metallization layer and a capacitor top plate 425A disposed in another metallization layer. The capacitor bottom plate 425B is electrically connected to a circuit 426 in the first IC die 402. The circuit 426 is on, over and/or in the semiconductor substrate 420, and may include devices disposed on, over and/or in the semiconductor substrate 420. The circuit 426 may include electrical connections, such as effectuated by metal contacts, metal lines, and/or metal vias in the metallization structure 422. A cross-section portion 428 of the first IC die 402 is generally identified in FIG. 4, which may be represented by any one of the cross-sectional views shown in FIGS. 1A-1 to 1A-3 as noted previously.

Similarly, the second IC die 404 includes a semiconductor substrate 430 and a metallization structure 432 over the semiconductor substrate 430. The semiconductor substrate 430 may comprise any semiconductor material and can include a bulk material (e.g., bulk silicon) and one or more epitaxial layers of a semiconductor material. The metallization structure 432 can include multiple ILD layers and metallization levels, which may be the same as or different from the ILD layers and metallization levels of the first IC die 402.

As illustrated in FIG. 4, the metallization structure 432 of the second IC die 404 may include a bond pad 434 in an uppermost metallization level. The second IC die 404 includes a circuit 436 on, over and/or in the semiconductor substrate 430. The bond pad 434 is electrically connected to the circuit 436, which may include one or more devices disposed on, over and/or in the semiconductor substrate 430. Similar to the IC device 402, the IC device 404 may include electrical connections, such as effectuated by metal contacts, metal lines, and/or metal vias in the metallization structure 432.

The capacitor top plate 425A of the first IC die 402 is bonded to a wire 440, and hence, the capacitor top plate 425A may further function as a bond pad. The bond wire 440 is further bonded to the bond pad 434 of the second IC die 404. Accordingly, the capacitor 424 is electrically coupled between the circuit 426 in the first IC die 402 and the circuit 436 in the second IC die 404 (via the wire 440 and bond pad 434). The capacitor 424 may be configured as a direct current (DC) isolator between the circuit 426 in the first IC die 402 and the circuit 436 in the second IC die 404. Accordingly, the capacitor 424 can provide a level of galvanic isolation between the circuit 426 in the first IC die 402 and the circuit 436 in the second IC die 404.

Generally, a signal path is disposed between the circuit 426 in the first IC die 402 and the circuit 436 in the second IC die 404. The signal path includes the capacitor 424, the bond wire 440, and the bond pad 434. In some examples, the second IC die 404 does not include a galvanic isolation capacitor in the signal path between the circuits 426, 436. In such examples, the capacitor 424 of the first IC die 402 may be required to be particularly robust in high electric fields that can cause lateral failure modes through discharge paths in the polyimide/mold materials. As noted previously, the breakdown characteristics of polyimide and mold materials are not as robust as inorganic dielectrics, e.g., SiO₂, and in high electric fields can lead to unpredictable and uncontrolled lateral failure modes. In the presence of the conductive posts of the present disclosure, high electric fields (e.g., which can be on the order of several kV/m or MV/m, or higher) encountered by the signal path of the capacitor 424 may cause discharge paths between the top plate 425A and the bottom plate 425B through a DTI that is more stringently controlled. Accordingly, overall reliability of the packaged devices may be improved, e.g., resulting in reduced early lifetime failures. Further, because the breakdown properties of inter-plate dielectric layers are better characterized, more reliable time-dependent dielectric breakdown (TDDB) and lifetime estimates as well as working voltage projections may be obtained in different HV application scenarios.

Continuing to refer to FIG. 4, the first IC die 402 and the second IC die 404 may include other bond pads (e.g., bond pads 450, 452) to which wires (e.g., wires 454, 456) may be bonded. Although not specifically illustrated, some wires may further be bonded to leads of the leadframe portion 406, which can provide for external electrical connectors external to the IC package 200 for a given application environment. Further, the IC package 400 may be implemented as a variety of package types such as a dual in-line package (DIP), small outline integrated circuit (SOIC) package, quad flat package (QFP), small outline package (SOP), ball grid array (BGA) package, chip scale package (CSP), and/or the like, depending on application.

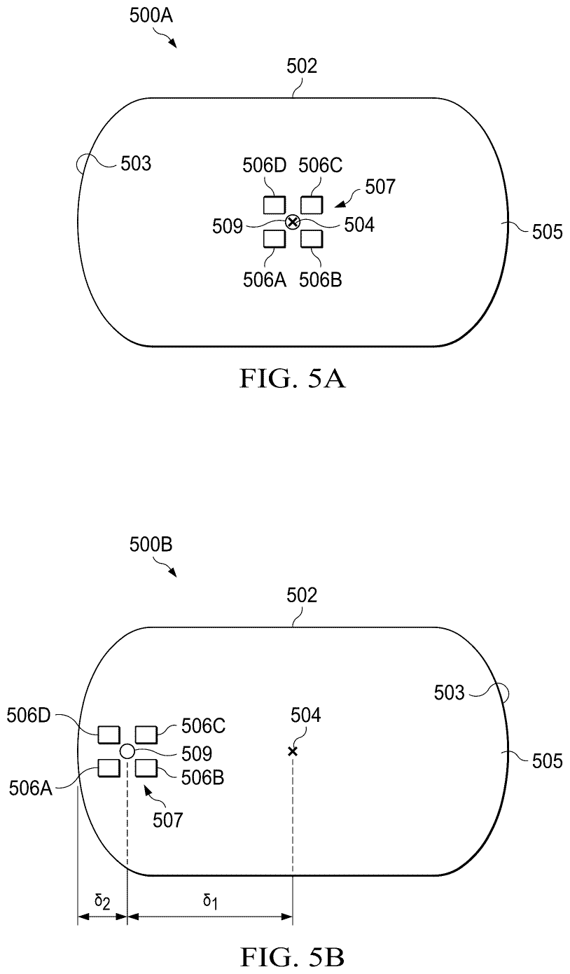

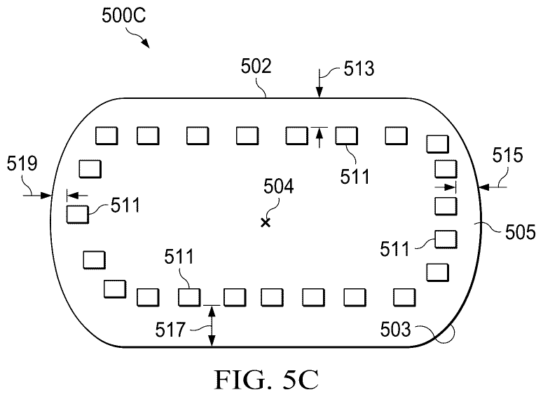

FIGS. 5A-5C depict plan views of a metal plate 502 of a galvanic isolation component with a plurality of conductive posts operable as discharge path direction conductors according to some examples of the present disclosure. In one example, the metal plate 502 is representative of a top plate of a capacitor such as the capacitor 102 shown in FIGS. 1A-1 to 1A-3, where a bottom surface 505 of the metal plate 502 is illustrated in a plan view. In another example, the metal plate 502 is representative of a bottom plate of a capacitor such as the capacitor 102 shown in FIGS. 1A-1 to 1A-3, where a top surface 505 of the metal plate 502 is illustrated in a plan view. In one example arrangement 500A shown in FIG. 5A, a plurality of conductive posts 506A-506D are arranged as a 2×2 grid 507 having a geometric center 509 that is co-aligned with a geometric center 504 of the metal plate 502. The geometric center 504 may be considered a centroid of the grid 507. The centroid of the grid 507, and of analogous grids, is defined as the arithmetic mean position of all the conductive posts in the grid as measured from the centers of the posts. In another example arrangement 500B shown in FIG. 5B, the grid 507 is spaced apart (e.g., laterally translated) from the geometric center 504 of the metal plate 502 such that the geometric center 509 of the grid 507 is positioned at distance δ₁ from the geometric center 504 of the metal plate 502. In such arrangements, the grid center 509 may be closer to an edge 503 of the metal plate 502, e.g., having a distance δ₂ from the edge 503, where δ₁>δ₂. In some arrangements, a grid spaced apart from the metal plate's center may be more effective in achieving appropriate breakdown characteristics. In some examples, therefore, distances δ₁ and/or δ₂ may be configured in various permutations and combinations relative to the surface 505 in order to optimize and/or customize the directionality of discharge paths as well as HV breakdown performance of the capacitor depending on a particular application. In another arrangement 500C shown in FIG. 5C, a plurality of conductive posts 511 may be arranged in a curvilinear fashion on the plate surface 505, where the posts 511 are proximate to the edge 503 of the metal plate 502, e.g., within a distance therefrom. In some examples, the posts 511 may be located at different distances, e.g., distances 513, 515, 517, 519, from a corresponding side of the edge 503. In still further arrangements, the conductive posts 511 may be arranged in a variety of spatial configurations with respect to the edge 503 and/or the plate center 504 as previously set forth.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, electroplating, or atomic layer deposition (ALD), etc. As another example, silicon nitride may be a silicon-rich silicon nitride or a silicon oxynitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc. relative to the spatial orientation of two components does not necessarily mean that one component is immediately or directly over or above the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. An integrated circuit (IC), comprising:
a semiconductor substrate;
a capacitor bottom plate over the semiconductor substrate;
a capacitor top plate over the capacitor bottom plate; and
a conductive post extending between the bottom plate and the top plate.

2. The IC of claim 1, wherein the conductive post touches a top surface of the bottom plate.

3. The IC of claim 2, wherein the conductive post is one of a plurality of conductive posts arranged in a grid having a center co-aligned with a center of the bottom plate.

4. The IC of claim 2, wherein the conductive post is one of a plurality of conductive posts arranged in a grid having a center laterally translated away from a center of the bottom plate.

5. The IC of claim 1, wherein the conductive post touches a bottom surface of the top plate.

6. The IC of claim 5, wherein the conductive post is one of a plurality of conductive posts are arranged in a grid having a center co-aligned with a center of the top plate.

7. The IC of claim 1, wherein the conductive post is one of a plurality of conductive posts arranged in a grid having a center co-aligned with a center of the top plate.

8. The IC of claim 1, wherein the conductive post is one of a plurality of conductive posts formed in an inter-level dielectric layer and electrically isolated from both the top plate and the bottom plate.

9. The IC of claim 1, wherein the conductive post is a metallic post having a height in a range from about 2 μm to about 4 μm and having a width in a range from about 0.5 μm to about 1.5 μm wide.

10. The IC of claim 1, wherein the conductive post is configured to direct a discharge path between the top plate and the bottom plate through a dielectric stack.

11. An integrated circuit (IC) package, comprising:
a first IC die including:
a capacitor including a bottom capacitor plate over a first semiconductor substrate, a top capacitor plate over the bottom capacitor plate, and a conductive post between the bottom capacitor plate and the top capacitor plate;
a second IC die including a circuit over or extending into a second semiconductor substrate; and
a wire bond connecting the top capacitor plate to the circuit.

12. The IC package of claim 11, wherein the conductive post is connected to a top surface of the bottom capacitor plate or a bottom surface of the top capacitor plate.

13. The IC package of claim 12, wherein the conductive post is one of a plurality of conductive posts arranged in a grid having a center co-aligned with a center of at least one of the bottom capacitor plate and the top capacitor plate.

14. The IC package of claim 12, wherein the conductive post is one of a plurality of conductive posts arranged in a grid having a center laterally translated from a center of at least one of the bottom capacitor plate and the top capacitor plate.

15. The IC package of claim 11, wherein the conductive post is one of a plurality of conductive posts formed in an inter-level dielectric layer and electrically isolated from both the top capacitor plate and the bottom capacitor plate.

16. The IC package of claim 11, wherein the conductive post is configured to direct a discharge path between the top capacitor plate and the bottom capacitor plate through a dielectric stack.

17. A method of fabricating an integrated circuit (IC), comprising:
forming a metal bottom plate of a capacitor over a semiconductor substrate;
forming a conductive post over the bottom plate; and
forming a metal top plate of the capacitor over the conductive post, wherein the conductive post extends between the bottom plate and the top plate.

18. The method of claim 17, wherein the conductive post touches a top surface of the bottom plate.

19. The method of claim 18, wherein conductive post is one of a plurality of conductive posts arranged in a grid having a center co-aligned with at a center of the bottom plate.

20. The method of claim 18, wherein the conductive post is one of a plurality of conductive posts arranged in a grid having a center laterally translated from a center of the bottom plate.

21. The method of claim 17, wherein the conductive post touches a bottom surface of the top plate.

22. The method of claim 17, wherein the conductive post is one of a plurality of conductive posts arranged in a grid having a center co-aligned with a center of the top plate.

23. The method of claim 17, wherein the conductive post is one of a plurality of conductive posts formed in an inter-level dielectric layer and electrically isolated from both the top plate and the bottom plate.

24. The method of claim 17, wherein the conductive post is configured to direct a discharge path between the top plate and the bottom plate through a dielectric stack.
